(19) United States
(12) Patent Application Publication
(10) Pub. No.: US 2026/0013299 A1
(43) Pub. Date: Jan. 8, 2026

(54) DISPLAY PANEL AND ELECTRONIC DEVICE INCLUDING THE SAME

(71) Applicant: Samsung Display Co., Ltd., Yongin-si (KR)

(72) Inventors: Daehyun Kim, Yongin-si (KR); Heyjin Shin, Yongin-si (KR); Mihae Kim, Yongin-si (KR); Hyeonjun Yoon, Yongin-si (KR); Wonkyu Kwak, Yongin-si (KR); Sunghwan Kim, Yongin-si (KR)

(21) Appl. No.: 19/257,233

(22) Filed: Jul. 1, 2025

(30) Foreign Application Priority Data
Jul. 3, 2024 (KR) 10-2024-0087819
Jul. 10, 2024 (KR) 10-2024-0091359

(51) Int. Cl. H10H 29/49; H10D 86/40; H10D 86/60; H10D 86/80; H10H 29/32; H10H 29/37; H10K 59/121; H10K 59/122; H10K 59/131

(52) U.S. Cl. CPC H10H 29/49; H10H 29/32; H10H 29/37; H10K 59/1213; H10K 59/1216; H10K 59/122; H10K 59/131; H10D 86/421; H10D 86/441; H10D 86/60; H10D 86/80

(57) ABSTRACT

A display panel includes first and second pixel circuits adjacent to each other in a first direction, data lines extending in a second direction and electrically connected to each of the first pixel circuit and the second pixel circuit, a first insulating layer on the data lines, a voltage layer on the first insulating layer, a second insulating layer on the voltage layer, and a light-emitting diode including a pixel electrode on the second insulating layer, an opposite electrode on the pixel electrode, and an emission layer between the pixel electrode and the opposite electrode, wherein the voltage layer includes a plurality of main portions spaced apart from each other, and bridge portions connecting the plurality of main portions, and the main portions include a first main portion positioned between the data lines and the pixel electrode and overlapping the data lines and the pixel electrode.

### CROSS-REFERENCE TO RELATED APPLICATION

The present application claims priority to and the benefit of Korean Patent Application No. 10-2024-0087819, filed on Jul. 3, 2024, and 10-2024-0091359, filed on Jul. 10, 2024, in the Korean Intellectual Property Office, the entire disclosures of each of which are incorporated herein by reference.

### BACKGROUND

### 1. Field

Aspects of one or more embodiments relate to a display panel and an electronic device including the display panel.

### 2. Description of the Related Art

In recent years, display panels have been used in electronic devices for various purposes. As the range of uses of display panels expands, consumer demand for high-quality display panels has increased. Manufacturing high-quality display panels may involve placing electronic components of various configurations in a narrow area.

The above information disclosed in this Background section is only for enhancement of understanding of the background and therefore the information discussed in this Background section does not necessarily constitute prior art.

### SUMMARY

Aspects of some embodiments include a display panel and an electronic device including the display panel.

Additional aspects will be set forth in part in the description which follows and, in part, will be apparent from the description, or may be learned by practice of the presented embodiments of the disclosure.

According to some embodiments of the present disclosure, a display panel may include a first pixel circuit and a second pixel circuit, which are on a substrate and each include a driving transistor and a storage capacitor, and are adjacent to each other in a first direction, data lines extending in a second direction and electrically connected to each of the first pixel circuit and the second pixel circuit, the second direction crossing the first direction, a first insulating layer on the data lines, a voltage layer on the first insulating layer, a second insulating layer on the voltage layer, and a light-emitting diode including a pixel electrode on the second insulating layer, an opposite electrode on the pixel electrode, and an emission layer between the pixel electrode and the opposite electrode, wherein the voltage layer includes a plurality of main portions spaced apart from each other, and bridge portions connecting the plurality of main portions, and the main portions include a first main portion positioned between the data lines and the pixel electrode and overlapping the data lines and the pixel electrode.

According to some embodiments, the main portions and the bridge portions of the voltage layer may be integrally connected to each other.

According to some embodiments, a data line electrically connected to the first pixel circuit and a data line electrically connected to the second pixel circuit may be arranged symmetrically with respect to an imaginary line between the first pixel circuit and the second pixel circuit.

According to some embodiments, the display panel may further include data connection lines configured to transmit data signals to pixel circuits other than the first pixel circuit and the second pixel circuit and passing through each of the first pixel circuit and the second pixel circuit, wherein the first main portion overlaps the data connection lines.

According to some embodiments, a data connection line passing through the first pixel circuit and a data connection line passing through the second pixel circuit may be arranged symmetrically with respect to the imaginary line.

According to some embodiments, each of the first pixel circuit and the second pixel circuit may further include a switching transistor electrically connected to the driving transistor and the voltage layer, and a semiconductor layer of the driving transistor of each of the first pixel circuit and the second pixel circuit may include a material different from a material of a semiconductor layer of the switching transistor.

According to some embodiments, each of the first pixel circuit and the second pixel circuit further comprises a connection electrode electrically connecting the semiconductor layer of the driving transistor and the semiconductor layer of the switching transistor, a first conductive layer below the semiconductor layer of the driving transistor, and a second conductive layer between the first conductive layer and the semiconductor layer of the driving transistor. A connection point of the connection electrode and the semiconductor layer of the driving transistor overlaps the first conductive layer and the second conductive layer.

According to some embodiments, the storage capacitor of each of the first pixel circuit and the second pixel circuit comprises a first storage electrode and a second storage electrode overlapping each other, the first conductive layer comprises the first storage electrode, and the second conductive layer comprises the second storage electrode.

According to some embodiments, the semiconductor layer of the driving transistor may include an oxide semiconductor material, and the semiconductor layer of the switching transistor may include polysilicon.

According to some embodiments, the display panel may further include a hold capacitor electrically connected to the driving transistor and the voltage layer, wherein the hold capacitor includes a first hold electrode electrically connected to the voltage layer and a second hold electrode overlapping the first hold electrode.

According to some embodiments, the display panel may further include a conductive layer under the semiconductor layer of the driving transistor, and an insulating layer positioned between the conductive layer and the switching transistor.

According to some embodiments, the storage capacitor may include a first storage electrode and a second storage electrode that overlap each other, and the conductive layer may include the second storage electrode and the second hold electrode.

According to some embodiments, the first hold electrode may include a first lower hold electrode under the conductive layer with the insulating layer therebetween, and a first upper hold electrode positioned on an opposite side of the first lower hold electrode with the conductive layer therebetween.

According to some embodiments, the first upper hold electrode may include a material identical to that of the semiconductor layer of the driving transistor.

According to some embodiments, the display panel may further include a bank layer on the pixel electrode and including an opening that overlaps the pixel electrode, wherein the opening defined in the bank layer overlaps the first main portion.

According to some embodiments, a width of the first main portion may be greater than a width of the opening defined in the bank layer.

According to some embodiments, a width of the first main portion may be less than a width of the opening defined in the bank layer.

According to some embodiments, the main portions may include a second main portion, a third main portion, a fourth main portion, and a fifth main portion, the second to fifth main portions being arranged around the first main portion, in a plan view, the second main portion, the third main portion, the fourth main portion, and the fifth main portion may be arranged at corners of an imaginary rectangle centered on the first main portion, respectively, the second main portion and the third main portion may be arranged in the first direction, the fourth main portion may be spaced apart from the second main portion in the second direction, and the fifth main portion may be spaced apart from the third main portion in the second direction.

According to some embodiments, the bridge portions may include first bridge portions extending in a first diagonal direction oblique to the first direction and the second direction, and second bridge portions oblique to the first direction and the second direction and extending in a second diagonal direction crossing the first diagonal direction, one of the first bridge portions may connect the first main portion and the third main portion to each other, another one of the first bridge portions may connect the first main portion and the fourth main portion to each other, one of the second bridge portions may connect the first main portion and the second main portion to each other, and another one of the second bridge portions may connect the first main portion and the fifth main portion to each other.

According to some embodiments, the bridge portions may include first bridge portions extending in the first direction, and second bridge portions extending in the second direction, one of the first bridge portions may connect the second main portion and the third main portion to each other, another one of the first bridge portions may connect the fourth main portion and the fifth main portion to each other, one of the second bridge portions may extend from the first main portion and may be connected to the one of the first bridge portions between the second main portion and the third main portion, and another one of the second bridge portions may extend from the first main portion and may be connected to the other one of the first bridge portions between the fourth main portion and the fifth main portion.

According to some embodiments, the light-emitting diode may be electrically connected to the first pixel circuit, and the pixel electrode of the light-emitting diode may overlap an imaginary line between the first pixel circuit and the second pixel circuit.

According to some embodiments, the voltage layer may have a voltage level that is the same as that of a voltage applied to the opposite electrode of the light-emitting diode.

According to some embodiments of the present disclosure, an electronic device includes a display panel, and a lower cover forming an exterior of the electronic device and having an opening that exposes part of the display panel in a front surface thereof.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view illustrating an electronic device according to some embodiments;

FIG. 2 is an exploded perspective view illustrating an electronic device according to some embodiments;

FIG. 3 is a block diagram showing an electronic device according to some embodiments;

FIG. 4 is a plan view schematically illustrating a display panel according to some embodiments;

FIG. 5 is a side view schematically illustrating a display panel according to some embodiments;

FIG. 6 is a plan view schematically illustrating a display panel according to some embodiments;

FIGS. 7A and 7B are enlarged plan views of region VII of the display device of FIG. 6, according to some embodiments;

FIG. 8 is an equivalent circuit diagram of a light-emitting diode and a pixel circuit of a display panel according to some embodiments;

FIG. 9 is a plan view schematically illustrating pixel circuits of a display panel according to some embodiments;

FIG. 10 shows a cross-section of the display panel of FIG. 6 according to some embodiments, taken along the line X-X′ of FIG. 6;

FIGS. 11 to 19 are plan views according to a process of forming a pixel circuit of a display panel, according to some embodiments;

FIG. 20 is a plan view illustrating light-emitting diodes located on pixel circuits according to some embodiments, and FIG. 21 is a cross-sectional view taken along the line XXI-XXI′ of FIG. 20, according to some embodiments;

FIG. 22 is a cross-sectional view taken along the line XXI-XXI′ of FIG. 20, according to some embodiments;

FIG. 23 is a plan view illustrating a portion of a voltage layer of FIG. 19; and

FIG. 24 is a plan view illustrating a voltage layer on first and second pixel circuits according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

One or more embodiments will be described below in more detail with reference to the accompanying drawings. Those elements that are the same or are in correspondence are rendered the same reference numeral regardless of the figure number, and redundant descriptions thereof are omitted.

In the embodiments described below, terms such as “first” and “second” are used herein merely to describe a variety of elements, but the elements are not limited by the terms. Such terms are used only for the purpose of distinguishing one element from another element.

In the embodiments described below, an expression used in the singular encompasses the expression of the plural, unless it has a clearly different meaning in the context.

In the embodiments described below, terms such as “include” or “comprise” may be construed to denote a certain characteristic or element, or a combination thereof, but may not be construed to exclude the existence of or a possibility of addition of one or more other characteristics, elements, or combinations thereof.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or element is referred to as being “connected” to another layer, region, or element, it may be “directly connected” to the other layer, region, or element or may be “indirectly connected” to the other layer, region, or element with other layer, region, or element therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with other layer, region, or element therebetween.

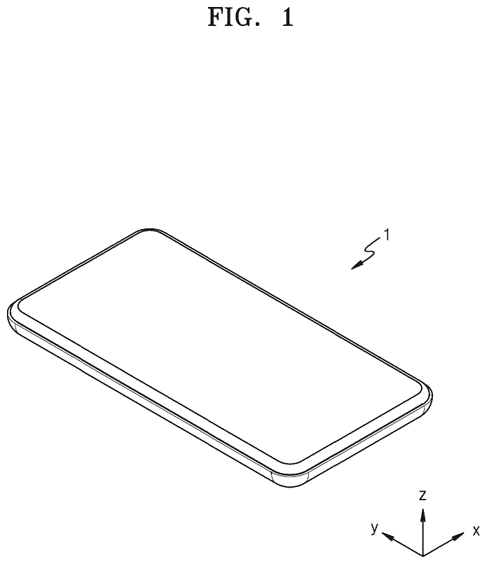

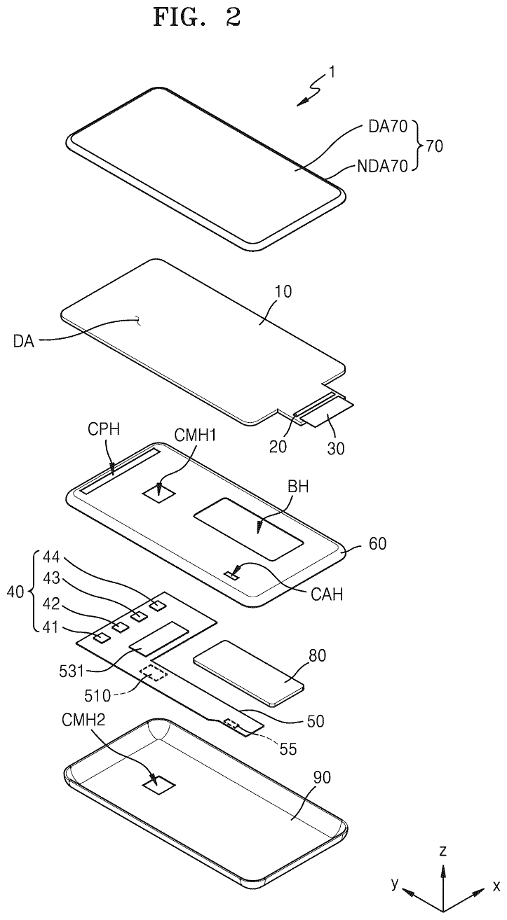

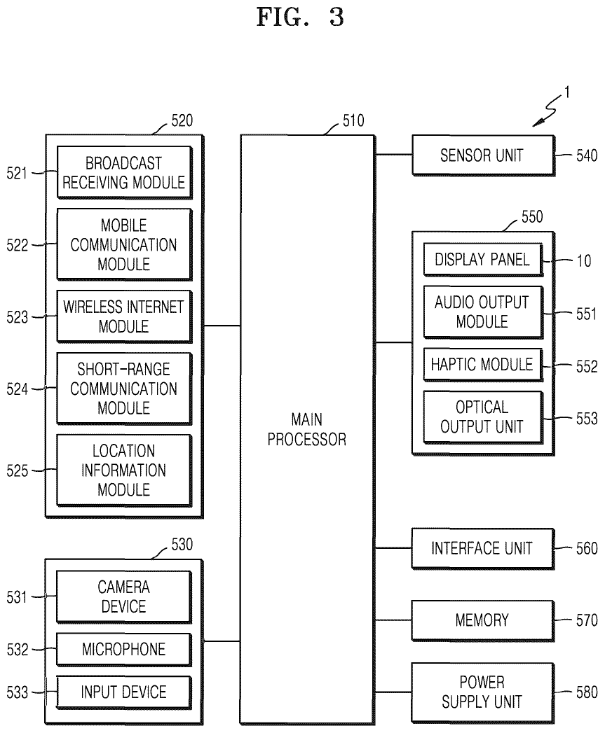

FIG. 1 is a perspective view illustrating an electronic device 1 according to some embodiments, FIG. 2 is an exploded perspective view illustrating the electronic device 1 according to some embodiments, and FIG. 3 is a block diagram showing the electronic device 1 according to some embodiments.

Referring to FIGS. 1 and 2, the electronic device 1, which is a device for displaying moving images (e.g., video images) or still images (e.g., static images), may be used not only for a portable electronic device, such as a mobile phone, a smartphone, a tablet personal computer (PC), a mobile communication terminal, an electronic notebook, an electronic book, a portable multimedia player (PMP), a navigation, or an ultra mobile PC (UMPC), but also as a display screen for various products such as televisions, laptops, monitors, billboards, and an Internet of things (IoT) device. The electronic device 1 according to some embodiments may be used for wearable devices such as smart watches, watch phones, glasses-type displays, and head-mounted displays (HMDs). The electronic device 1 according to some embodiments may be used for an instrument panel of a vehicle, a center fascia of a vehicle or a center information display (CID) located or arranged on or in a dashboard, or a room mirror display replacing a side view mirror of a vehicle, or may be used as a display located on the rear side of a front seat as an entertainment for backseat of a vehicle.

In FIGS. 1 and 2, for convenience of description, the electronic device 1 according to some embodiments is used as a smartphone. The electronic device 1 according to some embodiments may include a cover window 70, a display panel 10, a data driver 20, a display circuit board 30, a component 40, a bracket 60, a main circuit board 50, a battery 80, and a lower cover 90.

Herein, “left,” “right,” “up,” and “down” in a plan view indicate directions when the display panel 10 is viewed from the direction perpendicular to the display panel 10. For example, “left” indicates a −x direction, “right” indicates a +x direction, “up” indicates a +y direction, and “down” indicates a −y direction.

The electronic device 1 may be formed in a rectangular shape in a plan view. For example, the electronic device 1 may have a rectangular planar shape having a short side in the x direction and a long side in the y direction, as shown in FIG. 1. A corner at which the short side in the x direction and the long side in the y direction meet may be formed round to have a certain curvature or formed at a right angle. The planar shape of the electronic device 1 is not limited to a rectangle, and may be formed into other polygonal, elliptical, or irregular shapes.

The cover window 70 may be located on the display panel 10 to cover an upper surface of the display panel 10. Due to this, the cover window 70 may function to protect the upper surface of the display panel 10.

The cover window 70 may include a transparent cover unit DA70 corresponding to the display panel 10 and a light-shielding cover unit NDA70 surrounding the transparent cover unit DA70. The light-shielding cover unit NDA70 may include an opaque material (e.g., a colored opaque material) that blocks light. The light-shielding cover unit NDA70 may include a pattern that may be shown to the user when no images are displayed.

The display panel 10 may be located below the cover window 70. The display panel 10 may overlap the transparent cover unit DA70 of the cover window 70.

The display panel 10 may include a display area DA. The display area DA, which is an area where images are displayed, may include an area (hereinafter, referred to as “component area”) through which light emitted from the component 40 located below the display panel 10 passes. The component may include sensors, cameras, and the like that use visible light, infrared ray, or sound.

The display panel 10 may be a light-emitting display panel including a light-emitting diode. The light-emitting diode may include an organic light-emitting diode including an organic emission layer. According to some embodiments, the light-emitting diode may be an inorganic light-emitting diode including an inorganic material. The inorganic light-emitting diode may include a PN diode including inorganic semiconductor-based materials. When a voltage is applied in a forward direction to a PN junction diode, holes and electrons may be injected, and energy generated by recombination of the holes and electrons may be converted into light energy, to emit light of a certain color. The inorganic light-emitting diode described above may have a width of several to several hundred micrometers, and in some embodiments, the inorganic light-emitting diodes may be referred to as micro light-emitting diodes (LEDs).

The display panel 10 may be a rigid display panel that is rigid and is not easily bendable, or a flexible display panel that is relatively easily bendable, foldable, or rollable without damaging the display panel 10. For example, the display panel 10 may be a foldable display panel, a curved display panel with a curved display surface, a bended display panel in which an area other than a display surface is bent, a rollable display panel that may be rolled or unrolled, or a stretchable display panel.

The display panel 10 may be a transparent display panel that allows an object or background located on a lower surface of the display panel 10 to be visible from the upper surface of the display panel 10. Alternatively, the display panel 10 may be a reflective display panel capable of reflecting an object or background on the upper surface of the display panel 10.

The data driver 20 may be located on the display panel 10 in the form of an integrated circuit (IC). According to some embodiments, the data driver 20 may be located on the display circuit board 30.

The display circuit board 30 may be affixed to one side of the display circuit board 30. The display circuit board 30 may be a flexible printed circuit board (FPCB) that may be bent, a rigid printed circuit board (PCB) that is hard and is not easily bendable, or a composite printed circuit board including both an FPCB and a rigid PCB.

According to some embodiments, a touch sensor driving unit may be located on the display circuit board 30. The touch sensor driving unit may be formed as an IC. The touch sensor driving unit may be affixed on the display circuit board 30. The touch sensor driving unit may be electrically connected to touch electrodes of a touch screen layer of the display circuit board 30 through the display circuit board 30.

The touch screen layer of the display panel 10 may detect a user's touch input by using at least one of various touch methods such as a resistive film method or an electrostatic capacitance method. For example, when the touch screen layer of the display panel 10 detects a user's touch input in an electrostatic capacitive manner, the touch sensor driving unit may apply driving signals to driving electrodes of the touch electrodes and detect, through sensing electrodes of the touch electrodes, voltages charged in mutual electrostatic capacitances (hereinafter, referred to as “mutual capacitance”) between the driving electrodes and the sensing electrodes, thereby determining whether a user's touch is received. The user's touch may include a contact touch and a proximity touch. The contact touch indicates that a user's finger or an object such as a pen is in direct contact with the cover window 70 located on the touch screen layer. The proximity touch indicates that a user's finger or an object such as a pen is positioned close to the cover window 70, such as hovering. The touch sensor driving unit may transmit sensor data to a main processor 510 according to the detected voltages, and the main processor 510 may analyze the sensor data and calculate touch coordinates at which a touch input has occurred.

A control unit for supplying driving voltages for driving pixels of the display panel 10, a gate driver, and the data driver 20 may be located on the display circuit board 30.

The bracket 60 for supporting the display panel 10 may be located below the display panel 10. The bracket 60 may include plastic, metal, or both plastic and metal. A first camera hole CMH1 into which a camera device 531 is inserted, a battery hole BH in which the battery 80 is located, and a cable hole CAH through which a cable connected to the display circuit board 30 passes may be formed in the bracket 60. A component hole CPH overlapping the display panel 10 may be provided in the bracket 60. The component hole CPH may overlap the components 40 of the main circuit board 50 in a third direction (z direction). According to some embodiments, the display area DA of the display panel 10 may overlap the components 40 of the main circuit board 50 in the third direction (z direction). According to some embodiments, the component hole CPH may not be formed in the bracket 60.

According to some embodiments, the component 40 may include first to fourth components 41, 42, 43, and 44 that overlap the display panel 10. Each of the first to fourth components 41, 42, 43, and 44 may be provided as a proximity sensor, an illumination sensor, an iris sensor, a face recognition sensor, and a camera (or image sensor). The proximity sensor using infrared rays may detect an object located close to an upper surface of the electronic device 1, and the illumination sensor may detect a brightness of light incident on the upper surface of the electronic device 1. In addition, the iris sensor may photograph a person's iris located on the upper surface of the electronic device 1, and the camera may photograph an object located on the upper surface of the electronic device 1. The component 40 is not limited to a proximity sensor, an illumination sensor, an iris sensor, a face recognition sensor, and a camera, and various sensors to be described below may be arranged.

The main circuit board 50 and the battery 80 may be located below the bracket 60. The main circuit board 50 may be a printed circuit board or a FPCB.

The main circuit board 50 may include the main processor 510, the camera device 531, a main connector 55, and the components 40. The main processor 510 may be formed as an IC. The camera device 531 may be located on both the upper and lower surfaces of the main circuit board 50, and each of the main processor 510 and the main connector 55 may be located on either one of the upper and lower surfaces of the main circuit board 50.

The main processor 510 may control all functions of the electronic device 1. For example, the main processor 510 may output digital video data to the data driver 20 so that an image is displayed on the display panel 10. The main processor 510 may receive input of sensing data from the touch sensor driving unit. The main processor 510 may determine whether a user's touch is received according to the sensing data, and execute an operation corresponding to a direct touch or proximity touch of the user. The main processor 510 may be an application processor, a central processing unit, or a system chip, each of which include an IC.

The camera device 531 may process image frames of a still image, a moving image, or the like obtained by an image sensor in a camera mode, and output the processed image frames to the main processor 510. The camera device 531 may include at least one of a camera sensor (e.g., charge-coupled device (CCD), complementary metal-oxide-semiconductor (CMOS), or the like), a photo sensor (or image sensor), or a laser sensor. The camera device 531 may be connected to the image sensor of the component 40 overlapping a second display area DA2 and may process an image input to the image sensor.

A cable 35, which passes through the cable hole CAH defined in the bracket 60, may be connected to the main connector 55, and thus the main connector 55 may be electrically connected to the display circuit board 30.

In addition to the main processor 510, the camera device 531, and the main connector 55, the main circuit board 50 may further include a wireless communication unit 520, an input unit 530, a sensor unit 540, an output unit 550, an interface unit 560, a memory 570, and/or a power supply unit 580 shown in FIG. 3.

The wireless communication unit 520 may include at least one of a broadcast receiving module 521, a mobile communication module 522, a wireless Internet module 523, a short-range communication module 524, or a location information module 525.

The broadcast receiving module 521 may receive broadcast signals and/or broadcast-related information from an external broadcast management server via a broadcast channel. The broadcast channel may include satellite channels and terrestrial channels.

The mobile communication module 522 may transmit and receive wireless signals to and from at least one of an external terminal, a server on a mobile communication network, or a base station established according to technology standards or communication methods for mobile communication (e.g., Global System for Mobile Communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signal may include voice call signals, video call signals, or various forms of data according to text/multimedia message transmission and reception.

The wireless Internet module 523 indicates a module for wireless Internet connection. The wireless Internet module 523 may be configured to transmit and receive wireless signals in a communication network according to wireless Internet technologies. The wireless Internet technology may include, for example, Wireless LAN (WLAN), Wireless-Fidelity (Wi-Fi), Wi-Fi Direct, Digital Living Network Alliance (DLNA), and the like.

The short-range communication module 524, which ensures short-range communication, may support short-range communication by using at least one of Bluetooth, Radio Frequency Identification (RFID), Infrared Data Association (IrDA), Ultra Wideband (UWB), ZigBee, Near Field Communication (NFC), Wi-Fi, Wi-Fi Direct, or Wireless Universal Seral Bus (USB) technologies. The short-range communication module 524 may support wireless communication between the electronic device 1 and a wireless communication system, between the electronic device 1 and another electronic device, or the electronic device 1 and a network where another electronic device (or external server) is located, through wireless area networks. The wireless area networks may be wireless personal area networks. The other electronic device may be a wearable device capable of mutually exchanging data with (or linking with) the electronic device 1.

The location information module 525, which is a module for obtaining a location (or current location) of the electronic device 1, may include a global positioning system (GPS) module or a Wi-Fi module.

The input unit 530 may include an image input unit such as the camera device 531 for inputting an image signal, an audio input unit such as a microphone 532 for inputting an audio signal, and an input device 533 for receiving information from a user.

The camera device 531 may process image frames, such as still images or moving images, obtained by an image sensor in a video call mode or shooting mode. The processed image frames may be displayed on the display panel 10 or stored in the memory 570.

The microphone 532 may process external audio signals into electrical speech data. The speech data after processing may be variously used according to a function being performed (or application being run) in the electronic device 1.

The main processor 510 may control an operation of the electronic device 1 to correspond to information received via the input device 533. The input device 533 may include a mechanical input means, such as a button positioned on the rear surface or side surface of the electronic device 1, a dome switch, a jog wheel, or a jog switch, or a touch input means. The touch input means may include a touch screen layer of the display panel 10.

The sensor unit 540 may include one or more sensors configured to sense at least one of information within the electronic device 1, surrounding environment information of the electronic device 1, or user information, and generate a sensing signal corresponding thereto. Based on this sensing signal, the main processor 510 may control driving or operation of the electronic device 1 or perform data processing, functions, or operations associated with applications installed in the electronic device 1. The sensor unit 540 may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environment sensor (e.g., a barometer, a hygrometer, a thermometer, a radiation detection sensor, a heat detection sensor, or a gas detection sensor), or a chemical sensor (e.g., an electronic nose, a healthcare sensor, or a biometric recognition sensor).

The output unit 550 is for generating an output associated with vision, hearing, and tactile sensations, and may include at least one of the display panel 10, an audio output unit 551, a haptic module 552, or an optical output unit 553.

The display panel 10 may be configured to display (output) information processed in the electronic device 1. For example, the display panel 10 may be configured to display execution screen information of an application driven in the electronic device 1 or user interface (UI) or graphic user interface (GUI) information according to the execution screen information. The display panel 10 may include a display layer for displaying images and a touch screen layer for detecting a touch input of a user. Due to the above, the display panel 10 may function as one of the input devices 533 that provide an input interface between the electronic device 1 and the user, and at the same time, may function as the output units 550 that provide an output interface between the electronic device 1 and the user.

The audio output unit 551 may output audio data received from the wireless communication unit 520 or stored in the memory 570 in a call signal reception mode, a call mode or recording mode, a speech recognition mode, a broadcast reception mode, or the like. The audio output unit 551 may output audio signals associated with functions (e.g., call signal reception sound, message reception sound, or the like) performed in the electronic device 1. The audio output unit 551 may include a receiver or a speaker. At least one of the receiver or the speaker may be a sound generation device that is attached below the display panel 10 and vibrate the display panel 10 to output sound. The sound generation device may be a piezoelectric element, or piezoelectric actuator, that contracts and expands in response to an electric signal, or an exciter that generates a magnetic force by using a voice coil and vibrates the display panel 10.

The haptic module 552 may generate various tactile effects that may be felt by the user. The haptic module 552 may provide vibration to the user as a tactile effect. The haptic module 552 may not only transfer a tactile effect through direct contact, but also may be implemented such that the user may feel the tactile effect through the muscle sense of the fingers or arms.

The optical output unit 553 may output a signal for notifying the occurrence of an event by using light from a light source. Examples of events occurring in the electronic device 1 may include receiving a message, receiving a call signal, receiving a missed call, an alarm, a schedule alarm, a schedule reminder, receiving an e-mail, receiving information through an application, and the like. The signal output from the optical output unit 553 may be implemented as the electronic device 1 emits light of a single color or a plurality of colors from the front or rear thereof. The outputting of the signal may be terminated when the electronic device 1 detects the user's identification of the event.

The interface unit 560 serves as a passageway for various types of external devices connected to the electronic device 1. The interface unit 560 may include at least one of a wired/wireless headset port, an external charger port, a wired/wireless data port, a memory card port, a port connecting a device equipped with an identification module, an audio input/output (I/O) port, a video I/O port, or an earphone port. In response to an external device being connected to the interface unit 560, the electronic device 1 may perform an appropriate control associated with the connected external device.

The memory 570 may store data supporting various functions of the electronic device 1. The memory 570 may store a plurality of application programs running on the electronic device 1, data for an operation of the electronic device 1, and instructions. At least some of the plurality of applications may be downloaded from an external server through wireless communication. The memory 570 may store an application for an operation of the main processor 510, or may temporarily store input/output data, e.g., data such as a phonebook, messages, still images, and moving images. In addition, the memory 570 may store haptic data for vibration of various patterns provided to the haptic module 552, and audio data associated with various sounds provided to the audio output unit 551. The memory 570 may include a storage medium of at least one type from among a flash memory type, a hard disk type, a solid state disk type (SSD) type, a silicon disk drive (SDD) type, a multimedia card micro type, a card-type memory (e.g., secure digital (SD) or extreme digital (XD) memory), random access memory (RAM), static RAM (SRAM), read-only memory (ROM), electrically erasable programmable ROM (EEPROM), programmable ROM (PROM), magnetic memory, a magnetic disk, or an optical disk.

Under the control by the main processor 510, the power supply unit 580 may receive external power and internal power and supply power to each of elements included in the electronic device 1. The power supply unit 580 may include the battery 80. In addition, the power supply unit 580 may have a connection port, and the connection port may be configured as an example of the interface unit 560 to which an external charger supplying power for battery charging is electrically connected. Alternatively, the power supply unit 580 may be configured to charge the battery 80 in a wireless manner without using the connection port. The battery 80 may be arranged not to overlap the main circuit board 50 in the third direction (z direction). The battery 80 may overlap the battery hole BH of the bracket 60.

The lower cover 90 may form the exterior of the electronic device 1, and may have an opening that exposes part of the display panel 10 in a front surface thereof. The lower cover 90 is shaped such that a surface corresponding to the display panel 10 is opened, and may be assembled in connection with the display panel 10. The lower cover 90 may be positioned on an opposite side of the cover window 70 with the display panel 10 therebetween. The lower cover 90 may be located below the main circuit board 50 and the battery 80. The lower cover 90 may be fastened and fixed to the bracket 60. The lower cover 90 may form the exterior of a lower surface of the electronic device 1. The lower cover 90 may include plastic, metal, or both plastic and metal.

A second camera hole CMH2 through which a lower surface of the camera device 531 is exposed may be formed in the lower cover 90. A location of the camera device 531 and positions of the first and second camera holes CMH1 and CMH2 corresponding to the camera device 531 are not limited to the embodiments shown in FIGS. 1 and 2, and may be variously modified.

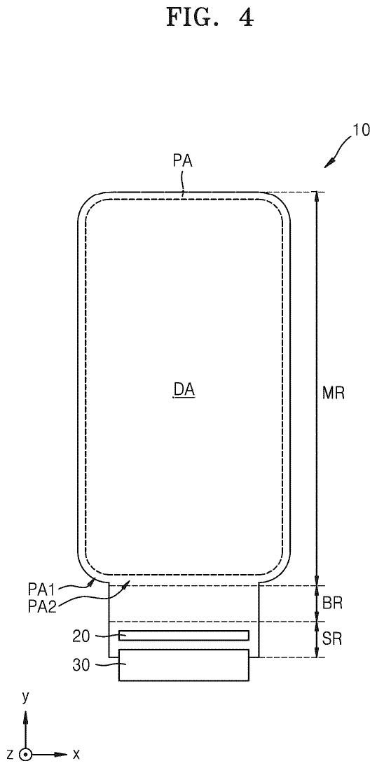

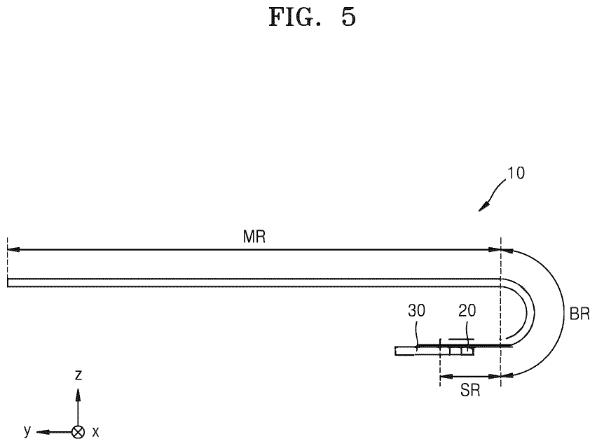

FIG. 4 is a plan view schematically illustrating the display panel 10 according to some embodiments, and FIG. 5 is a side view schematically illustrating the display panel 10 according to some embodiments.

The display panel 10 may include the display area DA and a peripheral area PA outside (e.g., surrounding or outside a footprint of) the display area DA. The display area DA is a portion or area at which images are displayed, and a plurality of pixels may be located in the display area DA. For example, the display area DA may have various shapes such as a circle, an ellipse, a polygon, and a specific shape. For example, FIG. 4 shows that the display area DA has an approximately rectangular shape with round edges, but embodiments according to the present disclosure are not limited thereto.

The peripheral area PA may be located outside the display area DA. The peripheral area PA may include a first peripheral area PA1, arranged to surround at least part of the display area DA, and a second peripheral area PA2 adjacent to one side of the display area DA and extending in a second direction (e.g., a −y direction). A width of the second peripheral area PA2 in a first direction (e.g., an x-axis direction) may be less than a width of the display area DA. This structure may make it easy for at least part of the second peripheral area PA2 to be bent.

A planar shape of the display panel 10 shown in FIG. 4 may be substantially identical to a shape of a substrate 100 included in the display panel 10. When it is described that the display panel 10 includes the display area DA and the peripheral area PA outside the display area DA, it may indicate that the substrate 100 includes the display area DA and the peripheral area PA outside the display area DA. Hereinbelow, for convenience of description, it is described that the substrate 100 includes the display area DA and the peripheral area PA.

The display panel 10 may include a main area MR, a bending area BR outside the main area MR, and a sub-area SR spaced apart from the main area MR with the bending area BR therebetween. The main area MR may be arranged at one side of the bending area BR, and the sub-area SR may be arranged on the other side of the bending area BR. The display panel 10 may be bent in the bending area BR, as shown in FIG. 5, and when viewed from a third direction (e.g., a z direction), at least part of the sub-area SR may overlap the main area MR. Although FIG. 5 shows the display panel 10 that is bent, embodiments according to the present disclosure are not limited thereto. According to some embodiments, the display panel 10 is a foldable display panel, and the display panel 10 may be bent with respect to a bending axis crossing the display area DA. According to some embodiments, the display panel 10 may not be bent. The sub-area SR may be a non-display area.

The data driver 20 may be located in the sub-area SR of the display panel 10. The data driver 20 may be located on the display panel 10 in the form of an IC. For example, the data driver 20 may be a data driving IC configured to generate data signals.

The display circuit board 30 may be affixed to an end of the sub-area SR of the display panel 10. The display circuit board 30 may be electrically connected to the data driver 20 or the like through a pad of the sub-area SR of the display panel 10.

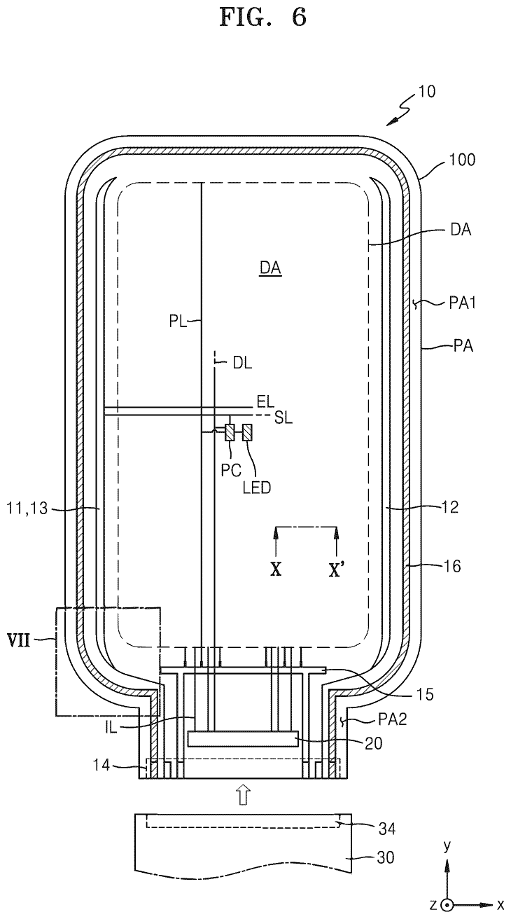

FIG. 6 is a plan view schematically illustrating the display panel 10 according to some embodiments.

Referring to FIG. 6, the display panel 10 may include the substrate 100. Various elements included in the display panel 10 may be located on the substrate 100.

The substrate 100 may include glass, metal, or polymer resin. The substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layer structure including two layers and an inorganic layer between the two layers, the two layers including the polymer resin described above.

A plurality of pixels may be located in the display area DA, and the display area DA may display images by using light emitted from the pixels. Each of the pixels may include a light-emitting diode LED, and the light-emitting diode LED may be electrically connected to a pixel circuit PC. The pixel circuit PC and the light-emitting diode LED may be located in the display area DA.

A gate driving circuit (e.g., a first scan driving circuit 11, a second scan driving circuit 12, or an emission control driving circuit 13), a pad 14, a first power supply line 15, and a second power supply line 16.

The first scan driving circuit 11 may provide a scan signal to the pixel circuit PC through a gate line SL. The second scan driving circuit 12 may be located on the opposite side of the first scan driving circuit 11 with the display area DA therebetween. Some of the pixel circuits PC located in the display area DA may be electrically connected to the first scan driving circuit 11, and the remaining one(s) may be connected to the second scan driving circuit 12. According to some embodiments, the second scan driving circuit 12 may be omitted.

The emission control driving circuit 13 may be located on the first scan driving circuit 11 side and may provide an emission control signal to a pixel P through an emission control line EL. In FIG. 6, the emission control driving circuit 13 may be located on only one side of the display area DA. However, embodiments according to the present disclosure are not limited thereto. According to some embodiments, the emission control driving circuit 13 may be located at opposite sides of the display area DA.

The pad 14 may be located in the second peripheral area PA2 of the substrate 100. The pad 14 may not be covered by an insulating layer, but may be exposed and electrically connected to the display circuit board 30. A pad 34 of the display circuit board 30 may be electrically connected to the pad 14 of the display panel 10.

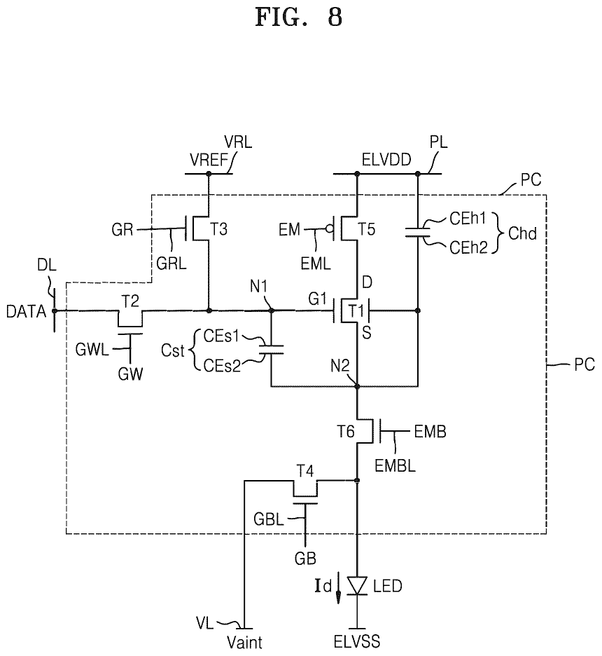

The display circuit board 30 may transmit a signal or power of a control unit to the display panel 10. Control signals generated by the control unit may be transmitted to a gate driving circuit through the display circuit board 30. In addition, the control unit may provide a first power voltage ELVDD and a second power voltage ELVSS (see FIG. 8) to first and second power supply lines 15 and 16, respectively. The first power voltage ELVDD (hereinafter, referred to as “driving voltage”) may be provided to each pixel circuit PC through a driving voltage line PL connected to the first power supply line 15, and the second power voltage ELVSS (hereinafter, referred to as “common voltage”) may be provided to an opposite electrode of the light-emitting diode LED connected to the second power supply line 16. The first power supply line 15 may extend in the first direction (e.g., the x direction). The second power supply line 16 may have a loop shape with one open side and partially surround the display area DA.

A data signal of the data driver 20 may be transmitted to the pixel circuit PC through an input line IL and a data line DL electrically connected to the input line IL.

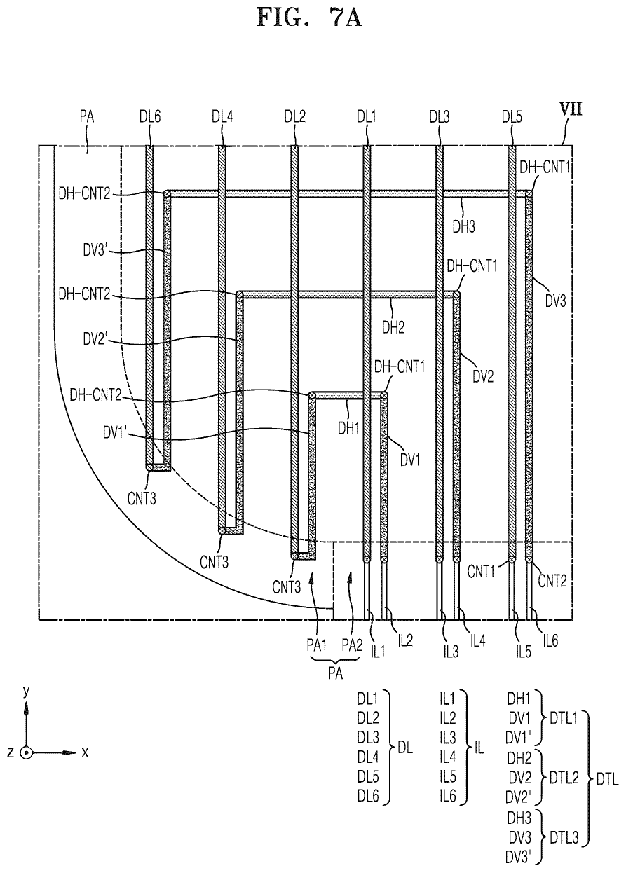

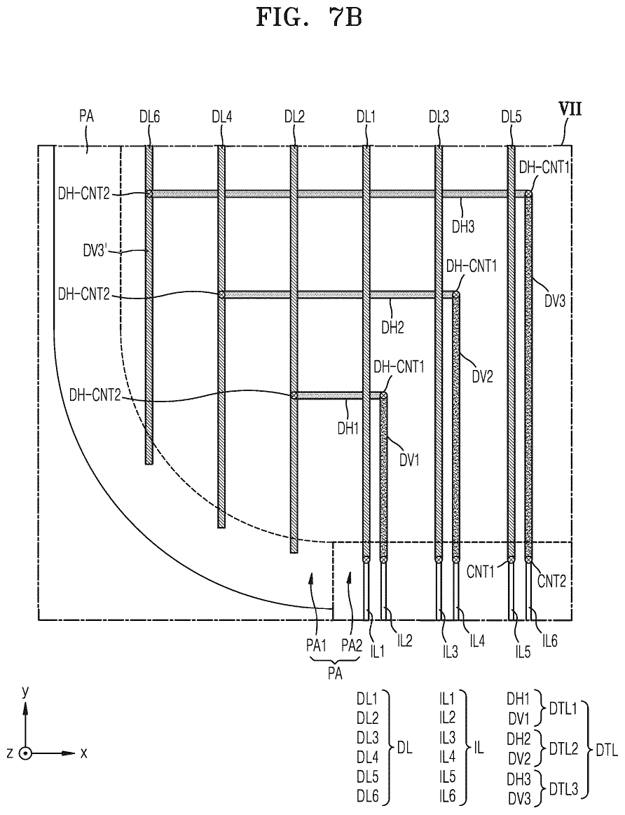

FIGS. 7A and 7B are enlarged plan views of the region VII of the display device of FIG. 6, according to some embodiments.

Referring to FIG. 7A, a data line DL extending in the second direction (e.g., the y direction) may be located in the display area DA, and the input line IL may be located in the peripheral area PA. The input line IL may be configured to transmit a data signal of the data driver 20 (see FIG. 6) to the data line DL. For convenience of description, FIG. 7A shows that the data line DL includes first to sixth data lines DL1, DL2, DL3, DL4, DL5, and DL6 and the input line IL includes first to sixth input lines IL1, IL2, IL3, IL4, IL5, and IL6. However, the number of the data lines DL and the number of the input lines IL may be seven or more.

Some of the data lines DL may be directly connected to an input line, but some of the other ones of the data lines DL may be electrically connected through a data transfer line DTL, which is between the input line IL and the data line DL corresponding thereto.

According to some embodiments, the first, third, and fifth data lines DL1, DL3, and DL5 may receive data signals from the first, third, and fifth input lines IL1, IL3, and IL5, respectively. The first, third, and fifth input lines IL1, IL3, and IL5 may be electrically connected to the first, third, and fifth data lines DL1, DL3, and DL5, respectively. The first, third, and fifth input lines IL1, IL3, and IL5 may be integrally formed as a single body with the first, third, and fifth data lines DL1, DL3, and DL5, respectively, or may be connected to the first, third, and fifth data lines DL1, DL3, and DL5 through a first contact hole CNT1, respectively, as shown in FIG. 7A.

According to some embodiments, the second, fourth, and sixth data lines DL2, DL4, and DL6 may receive data signals from the second, fourth, and sixth input lines IL2, IL4, and IL6 through first to third data transfer lines DTL1, DTL2, and DTL3, respectively. The second, fourth, and sixth input lines IL2, IL4, and IL6 may be electrically connected to the second, fourth, and sixth data lines DL2, DL4, and DL6 through the first to third data transfer lines DTL1, DTL2, and DTL3, respectively.

The first to third data transfer lines DTL1, DTL2, and DTL3 may be located in the display area DA. The second input line IL2 may be electrically connected to the second data line DL2 through the first data transfer line DTL1, the fourth input line IL4 may be electrically connected to the fourth data line DL4 through the second data transfer line DTL2, and the sixth input line IL6 may be electrically connected to the sixth data line DL6 through the third data transfer line DTL3.

One end of the first to third data transfer lines DTL1, DTL2, and DTL3 may be connected to the second, fourth, and sixth input lines IL2, IL4, and IL6 through the second contact hole CNT2, and the other end of each of the first to third data transfer lines DTL1, DTL2, and DTL3 may be connected to the second, fourth, and sixth data lines DL2, DL4, and DL6 through the third contact hole CNT3. In FIG. 7A, the second contact hole CNT2 and the third contact hole CNT3 are positioned in the peripheral area PA. However, embodiments according to the present disclosure are not limited thereto. According to some embodiments, the second contact hole CNT2 and/or the third contact hole CNT3 may be positioned in the display area DA.

According to some embodiments, the first to third data transfer lines DTL1, DTL2, and DTL3 may include first connection lines DH1, DH2, and DH3, second connection lines DV1, DV2, and DV3, and third connection lines DV1′, DV2′, and DV3′, respectively. The first connection lines DH1, DH2, and DH3 may extend in the first direction (e.g., the x direction), and the second connection lines DV1, DV2, and DV3 and the third connection lines DV1′, DV2′, and DV3′ may extend in the second direction (e.g., the y direction), which is substantially parallel to the data line DL.

The second, fourth, and sixth input lines IL2, IL4, and IL6 may be connected to the second connection lines DV1, DV2, and DV3 through the second contact hole CNT2, respectively, and the third connection lines DV1′, DV2′, and DV3′ may be connected to the second, fourth, and sixth data lines DL2, DL4, and DL6 through the third contact hole CNT3, respectively. Each of the first connection lines DH1, DH2, and DH3 may be connected to the second connection lines DV1, DV2, and DV3 and the third connection lines DV1′, DV2′, and DV3′ through a first connection contact hole DH-CNT1 and a second connection contact hole DH-CNT2, respectively.

According to some embodiments, the second connection lines DV1, DV2, and DV3 and the third connection lines DV1′, DV2′, and DV3′ may be located on the same layer, and the first connection lines DH1, DH2, and DH3 may be located on a layer different from a layer on which the second connection lines DV1, DV2, and DV3 and the third connection lines DV1′, DV2′, and DV3′ are located. In this case, being located on the same layer may mean being simultaneously formed through the same mask process and including the same material.

In FIG. 7A, the first to third data transfer lines DTL1, DTL2, and DTL3 include the first connection lines DH1, DH2, and DH3, the second connection lines DV1, DV2, and DV3, and the third connection lines DV1′, DV2′, and DV3′, respectively. However, embodiments according to the present disclosure are not limited thereto. According to some embodiments, as shown in FIG. 7B, the first to third data transfer lines DTL1, DTL2, and DTL3 may each include the first connection lines DH1, DH2, and DH3 and the second connection lines DV1, DV2, and DV3. In this case, the second connection lines DV1, DV2, and DV3 may be electrically connected to data lines, e.g., the second, fourth, and sixth data lines DL2, DL4, and DL6, through the second connection contact hole DH-CNT2, respectively.

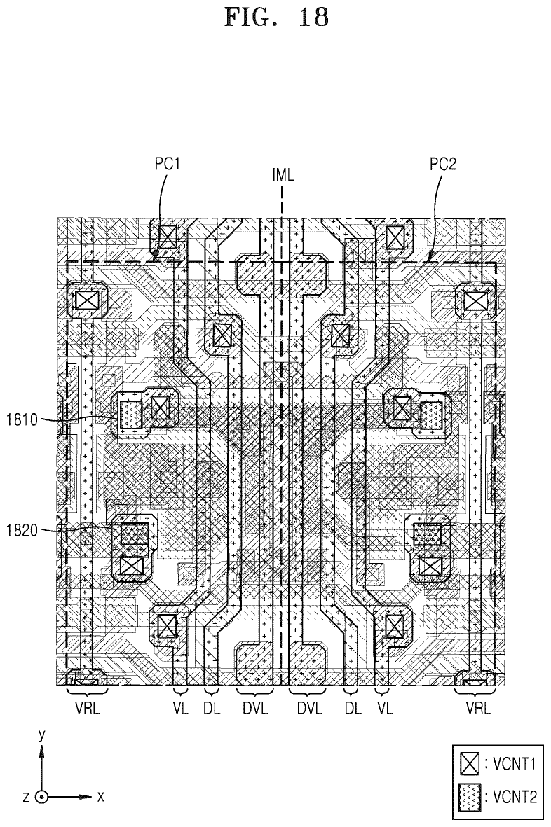

In FIGS. 7A and 7B, a structure in which one connection line extending in the second direction (e.g., the y direction) is located between two adjacent data lines DL. However, embodiments according to the present disclosure are not limited thereto. According to some embodiments, as described with reference to FIG. 18, two connection lines (e.g., data connection lines DVL of FIG. 18) may be located between two adjacent data lines DL.

FIG. 8 is an equivalent circuit diagram of the light-emitting diode LED and the pixel circuit PC of the display panel 10 (see FIG. 6) according to some embodiments.

Referring to FIG. 8, the pixel circuit PC connected to the light-emitting diode LED may include a plurality of transistors and a plurality of capacitors. According to some embodiments, the pixel circuit PC may include first to sixth transistors T1, T2, T3, T4, T5, and T6, a storage capacitor Cst, and a hold capacitor Chd. The first transistor T1 may be a driving transistor configured to output a driving current corresponding to a data signal, and the second to sixth transistors T2, T3, T4, T5, and T6 may be switching transistors configured to transfer signals. A first terminal (first electrode) of each of the first to sixth transistors T1, T2, T3, T4, T5, and T6 may be a source or a drain, and a second terminal (second electrode) may be a terminal different from the first terminal. For example, when the first terminal is the drain, the second terminal may be the source.

According to some embodiments, one or more of the first to sixth transistors T1, T2, T3, T4, T5, and T6 may be a p-channel metal-oxide-semiconductor field-effect transistor(s) (MOSFET; PMOS), and the remaining one(s) may be n-channel MOSFET(s) (NMOS). For example, the fifth transistor T5 may be a PMOS, and the first, second, third, fourth, and sixth transistors T1, T2, T3, T4, and T6 may be NMOSs. According to some embodiments, the fifth transistor T5 and the sixth transistor T6 may be PMOSs, and the first, second, third, and fourth transistors T1, T2, T3, and T4 may be NMOSs. Alternatively, the first to sixth transistors T1, T2, T3, T4, T5, and T6 may all be NMOSs or may all be PMOSs.

One or more of the first to sixth transistors T1, T2, T3, T4, T5, and T6 may be a transistor having a low-temperature polycrystalline silicon (LTPS) semiconductor layer, and one or more of the first to sixth transistors T1, T2, T3, T4, T5, and T6 may be a transistor having an oxide semiconductor layer. For example, the fifth transistor T5 may include a semiconductor layer including polycrystalline silicon with high reliability, and the first, second, third, fourth, and sixth transistors T1, T2, T3, T4, and T6 may include an oxide semiconductor layer with high carrier mobility and low leakage current.

Hereinbelow, embodiments are mainly described in which the fifth transistor T5 is a PMOS including a silicon semiconductor, and the first, second, third, fourth, and sixth transistors T1, T2, T3, T4, and T6 are NMOSs including an oxide semiconductor.

The pixel circuit PC may be electrically connected a gate line configured to transmit a signal to a gate of each of the first to sixth transistors T1, T2, T3, T4, T5, and T6. For example, the pixel circuit PC may be connected to a scan line GWL configured to transmit a scan signal GW, an initialization gate line GBL configured to transmit an initialization signal GB, a reference gate line GRL configured to transmit a reference signal GR, a first emission control line EML configured to transmit a first emission control signal EM, a second emission control line EMBL configured to transmit a second emission control signal EMB, and the data line DL configured to transmit a data signal DATA. In addition, the pixel circuit PC may be connected to a driving voltage line PL configured to transfer a driving voltage ELVDD, a reference voltage line VRL configured to transfer a reference voltage Vref, and an initialization voltage line VL configured to transfer an initialization voltage Vaint.

The first transistor T1 may be electrically connected between the driving voltage line PL and a second node N2. The first transistor T1 may include a gate G1 connected to a first node N1, a first terminal electrically connected to the driving voltage line PL, and a second terminal connected to the second node N2. The first terminal may be a drain D and the second terminal may be a source S.

The first terminal of the first transistor T1 may be connected to the driving voltage line PL via the fifth transistor T5, and the second terminal of the first transistor T1 may be connected to a pixel electrode of the light-emitting diode LED. The first transistor T1 may receive the data signal DATA in response to a switching operation of the second transistor T2 and control an amount of current of a driving current Id flowing to the light-emitting diode LED.

The second transistor T2 may be electrically connected between the data line DL and the first node N1. The second transistor T2 may include a gate connected to the scan line GWL, a first terminal connected to the data line DL, and a second terminal connected to the first node N1. The second transistor T2 may be turned on according to the scan signal GW received via the scan line GWL to electrically connect the data line DL and the first node N1, and may transfer the data signal DATA received via the data line DL to the first node N1.

The third transistor T3 may be electrically connected between the first node N1 and the reference voltage line VRL. The third transistor T3 may include a gate connected to the reference gate line GRL, a first terminal connected to the first node N1, and a second terminal connected to the reference voltage line VRL. The third transistor T3 may be turned on according to the reference signal GR received via the reference gate line GRL and may transfer the reference voltage Vref received via the reference voltage line VRL to the first node N1.

The fourth transistor T4 may be electrically connected between the first transistor T1 and the initialization voltage line VL. The fourth transistor T4 may include a gate connected to the initialization gate line GBL, a first terminal connected to a second terminal of the sixth transistor T6 and the light-emitting diode LED, and a second terminal connected to the initialization voltage line VL. The fourth transistor T4 may be turned on according to the initialization signal GB received via the initialization gate line GBL and may transfer the initialization voltage Vaint received via the initialization voltage line VL to the pixel electrode of the light-emitting diode LED.

The fifth transistor T5 may be electrically connected to the driving voltage line PL and the first transistor T1. The fifth transistor T5 may include a gate connected to the first emission control line EML, a first terminal connected to the driving voltage line PL, and a second terminal connected to the first terminal of the first transistor T1. The fifth transistor T5 may be turned on or off according to the first emission control signal EM received via the first emission control line EML.

The sixth transistor T6 may be connected to the first transistor T1 and the light-emitting diode LED. The sixth transistor T6 may include a gate connected to the second emission control line EMBL, a first terminal connected to the second node N2, and a second terminal connected to the light-emitting diode LED. The sixth transistor T6 may be turned on according to the second emission control signal EMB received via the second emission control line EMBL and may electrically connect the second node N2 and the pixel electrode of the light-emitting diode LED.

In FIG. 8, the fifth transistor T5 and the sixth transistor T6 are operated in response to different emission control signals EM and EMB, respectively. However, embodiments according to the present disclosure are not limited thereto. According to some embodiments, the fifth transistor T5 and the sixth transistor T6 may be operated in response to the same emission control signal.

According to some embodiments, the reference signal GR may be substantially synchronized with the scan signal GW of the pixel circuit PC in the previous row. The initialization signal GB may be substantially synchronized with the scan signal GW. According to some embodiments, the initialization signal GB may be substantially synchronized with the scan signal GW of the pixel circuit PC in the next row or the reference signal GR.

The storage capacitor Cst may be connected between the first node N1 and the second node N2. In other words, the pixel circuit PC according to some embodiments may be a source follower-type circuit, in which the storage capacitor Cst is connected between the first node N1 and the second node N2. A first storage electrode CEs1 of the storage capacitor Cst may be connected to the first node N1 and a second storage electrode CEs2 may be connected to the second node N2. The storage capacitor Cst may store a threshold voltage of the first transistor T1 and a voltage corresponding to the data signal DATA.

According to some embodiments, the hold capacitor Chd may be connected between the driving voltage line PL and the second node N2. A first hold electrode CEh1 of the hold capacitor Chd may be connected to the driving voltage line PL and a second hold electrode CEh2 may be connected to the second node N2. The hold capacitor Chd may ensure that a voltage at the second node N2 of the first transistor T1 does not fluctuate and has a constant voltage when a surrounding signal fluctuates.

The light-emitting diode LED may include the pixel electrode connected to the second node N2 and an opposite electrode on the pixel electrode, and the opposite electrode may receive a common voltage ELVSS. The opposite electrode may be a common electrode shared among a plurality of light-emitting diodes LED.

In FIG. 8, the pixel circuit PC includes six transistors and two capacitors. However, embodiments according to the present disclosure are not limited thereto. According to some embodiments, the pixel circuit PC may include five transistors and two capacitors. According to some embodiments, the pixel circuit PC may include seven transistors and two capacitors. Additionally, according to some embodiments, the pixel circuit PC may include additional components or fewer components without departing from the spirit and scope of embodiments according to the present disclosure.

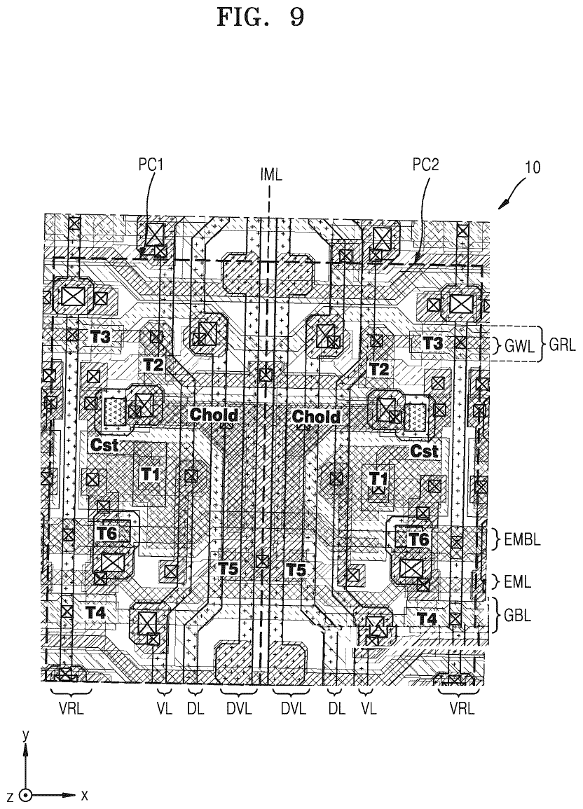

FIG. 9 is a plan view schematically illustrating pixel circuits of the display panel 10 according to some embodiments. In FIG. 9, for convenience of description, two pixel circuits, e.g., a first pixel circuit PC1 and a second pixel circuit PC2, located in the same row in the first direction (e.g., the x direction) are shown. However, embodiments according to the present disclosure are not limited thereto. The display panel 10 may include a plurality of pixel circuits located in rows in the first direction (e.g., the x direction) and columns in the second direction (e.g., the y direction).

Referring to FIG. 9, the first pixel circuit PC1 and the second pixel circuit PC2 may each include transistors and capacitors. According to some embodiments, each of the first pixel circuit PC1 and the second pixel circuit PC2 may include the first to sixth transistors T1, T2, T3, T4, T5, and T6, the storage capacitor Cst, and the hold capacitor Chd described above with reference to FIG. 8.

Transistors and capacitors of the first pixel circuit PC1 may be located symmetrically with transistors and capacitors of the second pixel circuit PC2. For example, the first transistor T1 of the first pixel circuit PC1 may be symmetrical to the first transistor T1 of the second pixel circuit PC2 with respect to an imaginary line IML passing between the first pixel circuit PC1 and the second pixel circuit PC2 in the second direction (e.g., the y direction). Similarly, with respect to the imaginary line IML, the second to sixth transistors T2, T3, T4, T5, and T6, the storage capacitor Cst, and the hold capacitor Chd of the first pixel circuit PC1 may be symmetrical to the second to sixth transistors T2, T3, T4, T5, and T6, the storage capacitor Cst, and the hold capacitor Chd, respectively.

Gate lines electrically connected to the first pixel circuit PC1 and the second pixel circuit PC2, e.g., the scan line GWL, the initialization gate line GBL, the reference gate line GRL, the first emission control line EML, and the second emission control line EMBL, may extend in the first direction (e.g., the x direction).

The first pixel circuit PC1 may be electrically connected to the data line DL passing through the first pixel circuit PC1, and the second pixel circuit PC2 may be electrically connected to the data line DL passing through the second pixel circuit PC2. The data line DL may extend in the second direction (e.g., the y direction). The data line DL electrically connected to the first pixel circuit PC1 and the data line DL electrically connected to the second pixel circuit PC2 may be symmetrical with respect to the imaginary line IML described above.

The first pixel circuit PC1 may be electrically connected to voltage lines passing through the first pixel circuit PC1, e.g., the reference voltage line VRL and the initialization voltage line VL. The second pixel circuit PC2 may be electrically connected to voltage lines passing through the second pixel circuit PC2, e.g., the reference voltage line VRL and the initialization voltage line VL. The reference voltage line VRL and the initialization voltage line VL electrically connected to the first pixel circuit PC1 may be symmetrical to the reference voltage line VRL and the initialization voltage line VL electrically connected to the second pixel circuit PC2, respectively, with respect to the imaginary line IML described above. The reference voltage line VRL and the initialization voltage line VL may each extend in the second direction (e.g., the y direction).

In some embodiments, the data connection line DVL may extend in the second direction (e.g., the y direction). The data connection line DVL may be a signal line corresponding to a portion of the data transfer line DTL described above with reference to FIG. 7A or 7B, e.g., one of the second connection lines DV1, DV2, and DV3 (see FIGS. 7A and 7B) or one of the third connection lines DV1′, DV2′, and DV3′ (see FIG. 7A). The data connection line DVL may be electrically connected to data lines of pixel circuits in other columns than the first and second pixel circuits PC1 and PC2 shown in FIG. 9, and may transmit data signals to the pixel circuits in the other columns.

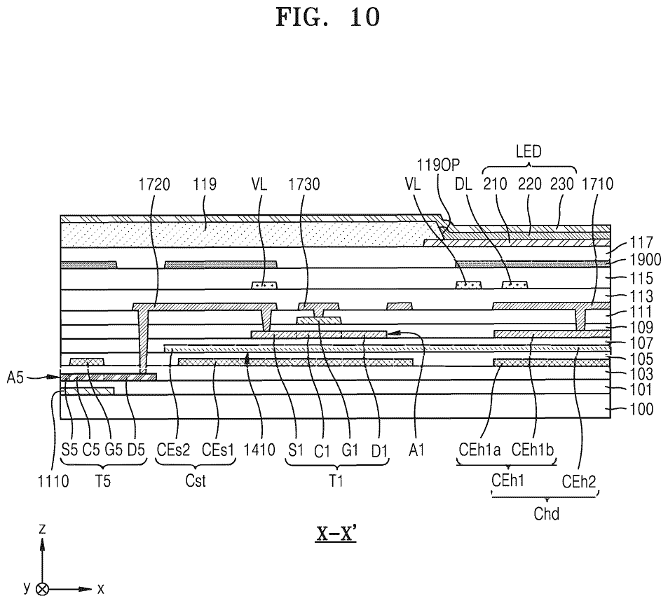

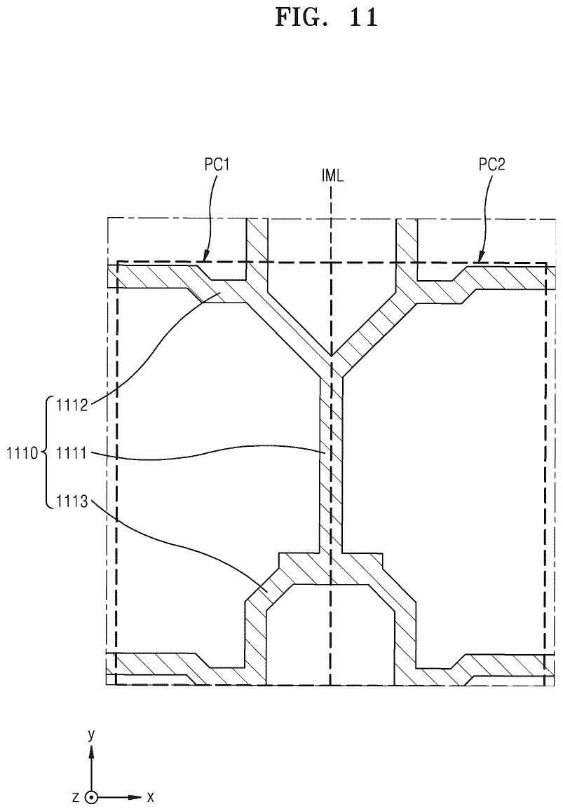

FIG. 10 shows a cross-section of the display panel 10 of FIG. 6 according to some embodiments, taken along the line X-X′ of FIG. 6.

Referring to FIG. 10, the display panel 10 may include a circuit layer including transistors and capacitors on the substrate 100, and a display element layer located on the circuit layer described above and including the light-emitting diode LED. The circuit layer may include the transistors and capacitors described above with reference to FIGS. 8 and 9, and FIG. 10 shows the first transistor T1, the fifth transistor T5, the storage capacitor Cst, and the hold capacitor Chd.

The substrate 100 may include a glass material, a ceramic material, a metal material, a plastic material, or a material having flexible or bendable properties. When the substrate 100 has the flexible or bendable properties, the substrate 100 may include polymer resin such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate, or cellulose acetate propionate (CAP).

The substrate 100 may have a single-layer or multi-layer structure of the materials, and may further include an inorganic layer in the case of the multi-layer structure. For example, the substrate 100 may have a structure in which a layer including the polymer resin described above and a barrier layer including an inorganic insulating material are alternately stacked.

A lower metal layer 1110 may be located on the substrate 100. The lower metal layer 1110 may include one or more materials selected from among aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu). In some embodiments, the lower metal layer 1110 may have a single layer including Mo, a double-layer structure in which a Mo layer and a Ti layer are stacked, or a triple-layer structure in which a Ti layer, an Al layer, and a Ti layer are stacked.

The lower metal layer 1110 may have a voltage level of a constant voltage. For example, the lower metal layer 1110 may have a voltage level (e.g., the driving voltage ELVDD) that is the same as that of the driving voltage line PL described with reference to FIG. 8. The lower metal layer 1110 may block light proceeding to a fifth semiconductor layer A5 of the fifth transistor T5.

The lower metal layer 1110 may be electrically connected to part of the driving voltage line PL (see FIG. 6) or the first power supply line 15 (see FIG. 6) in an area other than the display area DA (see FIG. 6), e.g., the peripheral area PA.

A buffer layer 101 may be located on the lower metal layer 1110. The buffer layer 101 may be an inorganic insulating layer including an inorganic insulating material such as silicon nitride and/or silicon oxide, or may have a single-layer or multi-layer structure including the materials described above.

A transistor including a silicon semiconductor layer may be located on the buffer layer 101. Regarding this, FIG. 10 shows the fifth semiconductor layer A5 of the fifth transistor T5. The fifth semiconductor layer A5 may include polysilicon. The fifth semiconductor layer A5 may include a channel region C5 and impurity regions S5 and D5 located at opposite sides of the channel region C5 and doped with impurities. One of the impurity regions S5 and D5 of the fifth semiconductor layer A5 may be a source, and the other one may be a drain.

A first gate insulating layer 103 may be located on the fifth semiconductor layer A5. The first gate insulating layer 103 may be an inorganic insulating layer including an inorganic insulating material such as silicon oxide, silicon nitride, and/or silicon oxynitride, and may have a single-layer or multi-layer structure including the materials described above.

A fifth gate electrode G5 may be located on the first gate insulating layer 103 and may overlap the channel region C5 of the fifth semiconductor layer A5. The first storage electrode CEs1 of the storage capacitor Cst and a sub-layer of the first hold electrode CEh1 of the hold capacitor Chd, e.g., a first lower hold electrode CEh1a, may be located on the same layer as the fifth gate electrode G5, e.g., the first gate insulating layer 103.

The fifth gate electrode G5, the first storage electrode CEs1 of the storage capacitor Cst, and the first lower hold electrode CEha of the hold capacitor Chd may include the same material. The fifth gate electrode G5, the first storage electrode CEs1 of the storage capacitor Cst, and the first lower hold electrode CEh1a of the hold capacitor Chd may include Al, Pt, Pd, Ag, Mg, Au, Ni, Nd, Ir, Cr, Li, Ca, Mo, Ti, W, and/or Cu, and may be formed of one or more layers including the materials described above. According to some embodiments, the fifth gate electrode G5, the first storage electrode CEs1 of the storage capacitor Cst, and the first lower hold electrode CEh1a of the hold capacitor Chd may have a single layer including Mo.

A second gate insulating layer 105 may be located on the fifth gate electrode G5, the first storage electrode CEs1 of the storage capacitor Cst, and the first lower hold electrode CEh1a of the hold capacitor Chd. The second gate insulating layer 105 may be an inorganic insulating layer including an inorganic insulating material such as silicon oxide, silicon nitride, and/or silicon oxynitride, and may have a single-layer or multi-layer structure including the materials described above. According to some embodiments, the second gate insulating layer 105 may include a material different from a material of the first gate insulating layer 103. For example, the first gate insulating layer 103 may include silicon oxide and the second gate insulating layer 105 may include silicon nitride.

A conductive layer 1410 (hereinafter, referred to as “fifth conductive layer”) may be located on the second gate insulating layer 105. The fifth conductive layer 1410 may overlap the first storage electrode CEs1 of the storage capacitor Cst and the first lower hold electrode CEh1a of the hold capacitor Chd. The fifth conductive layer 1410 may include a second electrode CEs2 of the storage capacitor Cst and the second hold electrode CEh2 of the hold capacitor Chd. A portion of the fifth conductive layer 1410 may be the second electrode CEs2 of the capacitor Cst, and another portion of the fifth conductive layer 1410 may be the second hold electrode CEh2 of the hold capacitor Chd. In other words, the second electrode CEs2 of the capacitor Cst and the second hold electrode CEh2 of the hold capacitor Chd may be integrally connected to each other.

The fifth conductive layer 1410, e.g., the second storage electrode CEs2 of the storage capacitor Cst and the second hold electrode CEh2 of the hold capacitor Chd, may include Al, Pt, Pd, Ag, Mg, Au, NI, Nd, Ir, Cr, Li, Ca, Mo, Ti, W, and/or Cu, and may be formed of one or more layers including the materials described above. According to some embodiments, the fifth conductive layer 1410 may be a single layer including Mo.

A first interlayer insulating layer 107 may be located on the fifth conductive layer 1410. The first interlayer insulating layer 107 may be an inorganic insulating layer including an inorganic insulating material such as silicon oxide, silicon nitride, and/or silicon oxynitride, and may have a single-layer or multi-layer structure including the materials described above. For example, the first interlayer insulating layer 107 may have a stack structure of a layer including silicon oxide and a layer including silicon nitride.

A first semiconductor layer A1 of the first transistor T1 and a first upper hold electrode CEh1b of the hold capacitor Chd may be located on the first interlayer insulating layer 107, and may include the same material. The first semiconductor layer A1 of the first transistor T1 may include an oxide semiconductor, and the oxide semiconductor may be an oxide semiconductor including at least one element selected from the group consisting of In, Ga, Sn, Zr, V, Hf, Cd, Ge, Cr, Ti, Al, Cs, Ce, or Zn. For example, the oxide semiconductor may include InSnZnO (ITZO) or InGaZnO (IGZO).

The first semiconductor layer A1 may include a channel region C1 and conductive regions S1 and D1 located at opposite sides of the channel region C1. Any one of the conductive regions S1 and D1 may be the source, and the other one may be the drain.

The first semiconductor layer A1 may be located on a layer different from a layer on which the fifth semiconductor layer A5 described above is located. A vertical distance from the substrate 100 and the first semiconductor layer A1 may be greater than a vertical distance from the substrate 100 to the fifth semiconductor layer A5.

The first upper hold electrode CEh1b of the hold capacitor Chd may overlap the fifth conductive layer 1410 and the first lower hold electrode CEh1a of the hold capacitor Chd below the fifth conductive layer 1410. The first upper hold electrode CEh1b of the hold capacitor Chd may be electrically connected to the first lower hold electrode CEh1a.

A third gate insulating layer 109 may be located on the first semiconductor layer A1 and the first upper hold electrode CEh1b of the hold capacitor Chd. The third gate insulating layer 109 may be an inorganic insulating layer including an inorganic insulating material such as silicon oxide, silicon nitride, and/or silicon oxynitride, and may have a single-layer or multi-layer structure including the materials described above. According to some embodiments, the third gate insulating layer 109 may be a single layer including silicon oxide.

In FIG. 10, the third gate insulating layer 109 is in contact with an upper surface of the first interlayer insulating layer 107 via a side surface of the first semiconductor layer A1. However, embodiments according to the present disclosure are not limited thereto. According to some embodiments, the third gate insulating layer 109 may be formed to have substantially the same pattern and/or substantially the same width as a first gate electrode G1 described in more detail below. In other words, the third gate insulating layer 109 may not be in contact with an upper surface of the first interlayer insulating layer 107 via a side surface of the first semiconductor layer A1.

The first gate electrode G1 may be located on the third gate insulating layer 109. The first gate electrode G1 may overlap the channel region C1 of the first semiconductor layer A1. The first gate electrode G1 may include Al, Pt, Pd, Ag, Mg, Au, Ni, Nd, Ir, Cr, Li, Ca, MO, Ti, W, and/or Cu, and may be formed of one or more layers including the materials describe above. According to some embodiments, the first gate electrode G1 may have a triple-layer structure of a Ti layer, an Al layer, and another Ti layer.

A second interlayer insulating layer 111 may be located on the first gate electrode G1. The second interlayer insulating layer 111 may be an inorganic insulating layer including an inorganic insulating material such as silicon oxide, silicon nitride, and/or silicon oxynitride, and may have a single-layer or multi-layer structure including the materials described above. According to some embodiments, the second interlayer insulating layer 111 may include a stack structure of a layer including silicon nitride and a layer including silicon oxynitride.

A first connection electrode 1710, a second connection electrode 1720, and a third connection electrode 1730 may be located on the same layer, e.g., the second interlayer insulating layer 111. The first connection electrode 1710, the second connection electrode 1720, and the third connection electrode 1730 may include the same material. The first connection electrode 1710, the second connection electrode 1720, and the third connection electrode 1730 may include Al, Pt, Pd, Ag, Mg, Au, Ni, Nd, Ir, Cr, Li, Ca, Mo, Ti, W, and/or Cu, and may be formed of one or more layers including the materials described above. According to some embodiments, the first connection electrode 1710, the second connection electrode 1720, and the third connection electrode 1730 may have a triple-layer structure of a Ti layer, an Al layer, and another Ti layer.

A first organic insulating layer 113 may be located on the first connection electrode 1710, the second connection electrode 1720, and the third connection electrode 1730. The first organic insulating layer 113 may include an organic insulating material such as acryl, benzocyclobutene (BCB), polyimide, or hexamethyldisiloxane (HMDSO).

The data line DL and the initialization voltage line VL may be located on the first organic insulating layer 113. The data line DL and the initialization voltage line VL may include Al, Pt, Pd, Ag, Mg, Au, Ni, Nd, Ir, Cr, Li, Ca, MO, Ti, W, and/or Cu, and may be formed of one or more layers including the materials describe above. According to some embodiments, the data line DL and the initialization voltage line VL may have a triple-layer structure of a Ti layer, an Al layer, and another Ti layer.

A second organic insulating layer 115 may be located on the data line DL and the initialization voltage line VL. The second organic insulating layer 115 may include an organic insulating material such as acryl, BCB, polyimide, or HMDSO.

A voltage layer 1900 may be located on the second organic insulating layer 115. In some embodiments, the voltage layer 1900 may have a voltage level of the driving voltage line PL described with reference to FIG. 8. The voltage layer 1900 may include Al, Pt, Pd, Ag, Mg, Au, Ni, Nd, Ir, Cr, Li, Ca, Mo, Ti, W, and/or Cu, and may be formed of one or more layers including the materials described above. According to some embodiments, the voltage layer 1900 may have a triple-layer structure of a Ti layer, an Al layer, and another Ti layer.

A third organic insulating layer 117 may be located on the voltage layer 1900. The third organic insulating layer 117 may include an organic insulating material such as acryl, BCB, polyimide, or HMDSO.

The light-emitting diode LED may be located on the third organic insulating layer 117. The light-emitting diode LED may include a pixel electrode 210, an intermediate layer 220, and an opposite electrode 230 on the third organic insulating layer 117.

An outer portion of the pixel electrode 210 may be covered by a bank layer 119, an inner portion of the pixel electrode 210 may overlap the intermediate layer 220 through an opening 119OP defined in the bank layer 119. The pixel electrode 210 may be arranged to correspond to each light-emitting diode LED, and the opposite electrode 230 may be arranged to correspond to a plurality of light-emitting diodes LED. In other words, the opposite electrode 230 may extend to overlap a plurality of pixel electrodes 210. The plurality of light-emitting diodes LED may share the opposite electrode 230, and a stack structure of the pixel electrode 210, the intermediate layer 220, and the opposite electrode 230 may correspond to the light-emitting diode LED.

The intermediate layer 220 may include an emission layer. In some embodiments, the intermediate layer 220 may further include an emission layer and a functional layer. The functional layer may include a hole transport layer (HTL), a hole injection layer (HIL), an electron transport layer (ETL), and/or an electron injection layer (EIL). According to some embodiments, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. The emission efficiency of a tandem light-emitting diode LED having a plurality of emission layers may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The opposite electrode 230 may include a conductive material with a low work function. The opposite electrode 230 may include a (semi-) transparent layer including Ag, Mg, Al, Pt, Pd, Au, Ni, Nd, Ir, Cr, Li, Ca, or an alloy thereof. Alternatively, the opposite electrode 230 may include a layer, including ITO, IZO, ZnO, or In₂O₃, on the (semi-)transparent layer including the materials described above.

According to some embodiments, an encapsulation layer may be located on the light-emitting diode LED. The encapsulation layer may include a first inorganic encapsulation layer, a second inorganic encapsulation layer, and an organic encapsulation layer therebetween.

FIGS. 11 to 19 are plan views according to a process of forming a pixel circuit of the display panel 10, according to some embodiments. In FIGS. 11 to 19, a process of forming elements corresponding to the first pixel circuit PC1 and the second pixel circuit PC2 described with reference to FIG. 9 is shown. For convenience of description, it is descried that the first pixel circuit PC1 is in an (i)^{th} row and a (j)^{th} column, and the second pixel circuit PC2 is in the (i)^{th} row and a (j+1)^{th} column.

Referring to FIG. 11, the lower metal layer 1110 may be located on a substrate. The lower metal layer 1110 may include a first portion 1111 extending in the second direction (e.g., the y direction) and a second portion 1112 and a third portion 1113 connected to the first portion 1111 and extending generally in the first direction (e.g., the x direction).

According to some embodiments, the first portion 1111 and the lower metal layer 1110 may be positioned on the imaginary line IML between the first pixel circuit PC1 and the second pixel circuit PC2. The second portion 1112 and the third portion 1113 of the lower metal layer 1110 may be on opposite sides with the first portion 1111 therebetween. The second portion 1112 and the third portion 1113 may extend generally in the first direction (e.g., the x direction), but may be locally bent. The lower metal layer 1110 may include a metallic material as described above with reference to FIG. 10.

The lower metal layer 1110 may have a voltage level of a constant voltage. For example, the lower metal layer 1110 may be electrically connected to the first power supply line 15 (see FIG. 6) at the periphery of the display area DA of the display panel 10 (see FIG. 6).

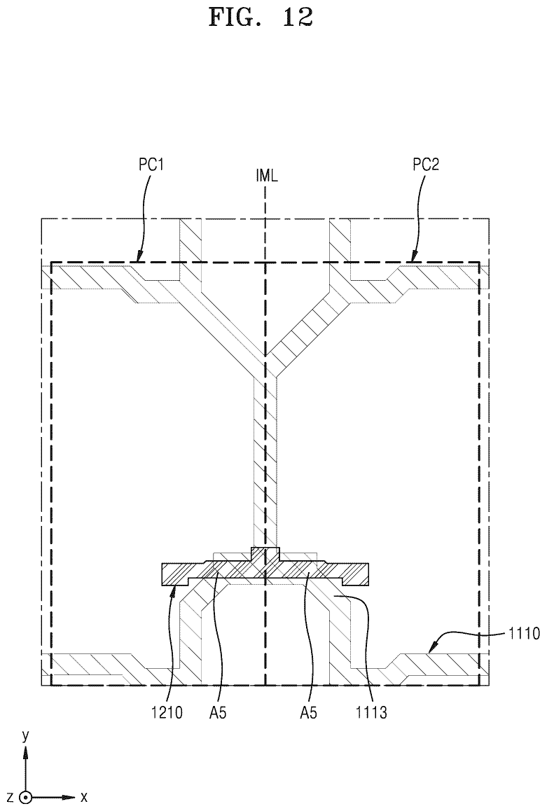

The buffer layer 101 (see FIG. 10) may be formed on the structure shown in FIG. 11, and a first silicon semiconductor pattern 1210 may be formed on the buffer layer 101 (see FIG. 10) as shown in FIG. 12. The first silicon semiconductor pattern 1210 may include silicon, for example, polysilicon.

Referring to FIG. 12, the first silicon semiconductor pattern 1210 may have an isolated shape and may extend in the first direction (e.g., the x direction). The first silicon semiconductor pattern 1210 may cross the imaginary line IML between the first pixel circuit PC1 and the second pixel circuit PC2. The first silicon semiconductor pattern 1210 may include the fifth semiconductor layer A5 of each of the first pixel circuit PC1 and the second pixel circuit PC2. In other words, the fifth semiconductor layer A5 of the first pixel circuit PC1 and the fifth semiconductor layer A5 of the second pixel circuit PC2 may be integrally connected to each other.

The first silicon semiconductor pattern 1210 may overlap the lower metal layer 1110. For example, the first silicon semiconductor pattern 1210 may overlap the third portion 1113 of the lower metal layer 1110. The fifth semiconductor layer A5 of each of the first pixel circuit PC1 and the second pixel circuit PC2 may overlap the third portion 1113 of the lower metal layer 1110.

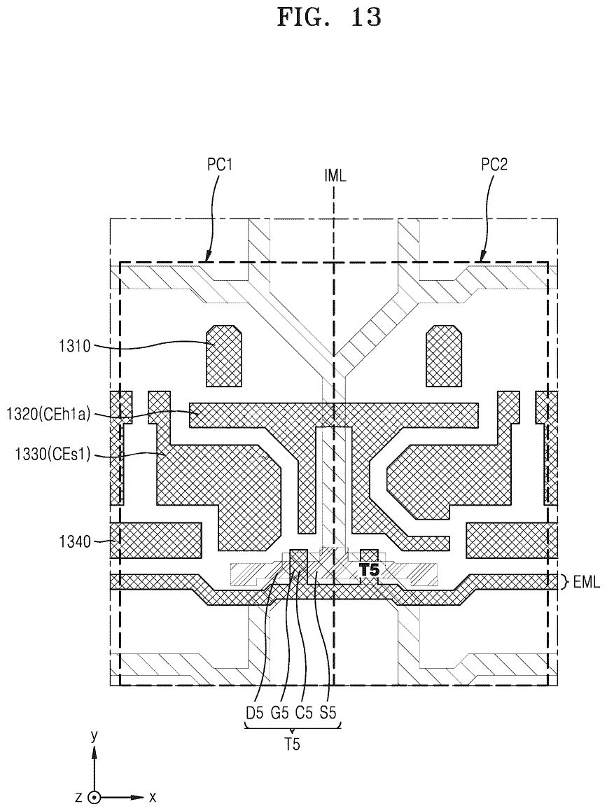

The first gate insulating layer 103 (see FIG. 10) may be formed on the structure shown in FIG. 12, and a gate line and a conductive layer may be formed, as shown in FIG. 13. In FIG. 13, it is shown that the first emission control line EML, a first conductive layer 1310, a second conductive layer 1320, a third conductive layer 1330, and a fourth conductive layer 1340 are formed on the first gate insulating layer 130 (see FIG. 10).

Referring to FIG. 13, the first emission control line EML, the first conductive layer 1310, the second conductive layer 1320, the third conductive layer 1330, and the fourth conductive layer 1340 may be spaced apart from each other. The first emission control line EML, the first conductive layer 1310, the second conductive layer 1320, the third conductive layer 1330, and the fourth conductive layer 1340 may include Al, Pt, Pd, Ag, Mg, Au, Ni, Nd, Ir, Cr, Li, Ca, Mo, Ti, W, and/or Cu, and may be formed of a layer or layers including the materials described above.

The first emission control line EML may extend in the first direction (e.g., the x direction) to pass through the first pixel circuit PC1 and the second pixel circuit PC2. The first emission control line EML may pass through pixel circuits arranged in the same row as the first pixel circuit PC1 and the second pixel circuit PC2.

The first emission control line EML may include the fifth gate electrode G5 of the fifth transistor T5 of each of the first pixel circuit PC1 and the second pixel circuit PC2. Part of the first emission control line EML may protrude to overlap the fifth semiconductor layer A5 and the fifth transistor T5, and the protruding part of the first emission control line EML may correspond to the fifth gate electrode G5 of the fifth transistor T5. The fifth semiconductor layer A5 (see FIG. 12) of the fifth transistor T5 may include the channel region C5 overlapping the fifth gate electrode G5 and doped regions S5 and D5 doped with impurities and located at opposite sides of the channel region C5. One of the doped regions S5 and D5 may be a source region and the other one may be a drain region. The source region and the drain region may correspond to a source electrode and a drain electrode, respectively. Positions of the source region and the drain region may be interchanged depending on the properties of the transistor.

The first conductive layer 1310, the second conductive layer 1320, the third conductive layer 1330, and the fourth conductive layer 1340 may be located in each of the first pixel circuit PC1 and the second pixel circuit PC2. The first conductive layer 1310, the second conductive layer 1320, the third conductive layer 1330, and the fourth conductive layer 1340 may each have an isolated shape. The first conductive layer 1310, the third conductive layer 1330, and the fourth conductive layer 1340 of the first pixel circuit PC1 and the first conductive layer 1310, the third conductive layer 1330, and the fourth conductive layer 1340 of the second pixel circuit PC2 may be symmetrically arranged with respect to the imaginary line IML described above.

The second conductive layer 1320 may have an isolated shape and may extend in the first direction (e.g., the x direction) to pass through the first pixel circuit PC1 and the second pixel circuit PC2. The second conductive layer 1320 may cross the imaginary line IML between the first pixel circuit PC1 and the second pixel circuit PC2. The second conductive layer 1320 may include a stem portion extending in the first direction (e.g., the x direction) and a branch portion branching from the stem portion and protruding in the second direction (e.g., the −y direction). The branch portion of the first pixel circuit PC1 and the branch portion of the second pixel circuit PC2 may be substantially symmetrical to each other with respect to the imaginary line IML between the first pixel circuit PC1 and the second pixel circuit PC2.

The second conductive layer 1320 may include the first lower hold electrode CEh1a, which is a sub-layer of the first hold electrode CEh1 of the hold capacitor Chd described with reference to FIG. 10. In other words, the first lower hold electrode CEh1a of the hold capacitor Chd of the first pixel circuit PC1 may be integrally connected to the first lower hold electrode CEh1a of the hold capacitor Chd of the second pixel circuit PC2.

The third conductive layer 1330 positioned in each of the first pixel circuit PC1 and the second pixel circuit PC2 may include the first storage electrode CEs1 of the storage capacitor Cst described with reference to FIG. 10.

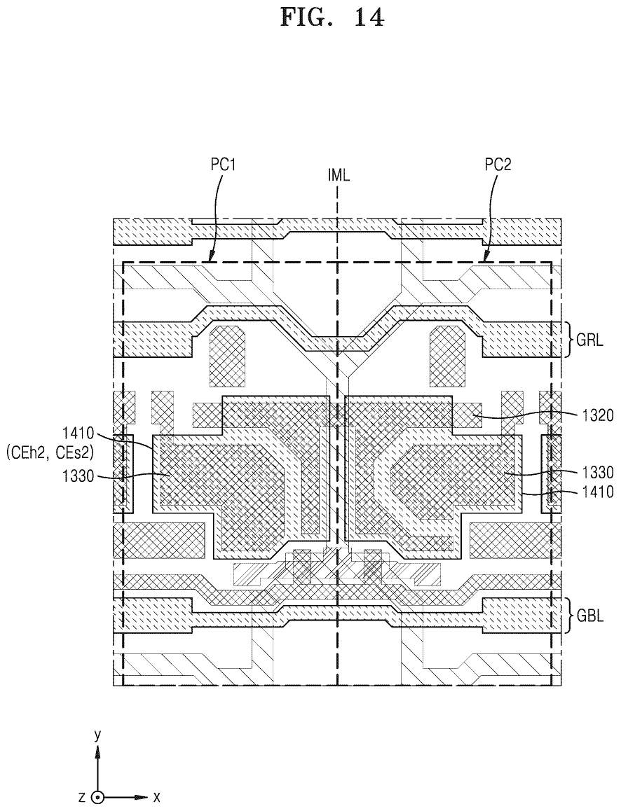

The second gate insulating layer 105 (see FIG. 10) may be formed on the structure shown in FIG. 13, and a gate line and a conductive layer may be formed, as shown in FIG. 14. In FIG. 14, the initialization gate line GBL, the reference gate line GRL, and the fifth conductive layer 1410 are formed on the second gate insulating layer 105 (see FIG. 10).

Referring to FIG. 14, the initialization gate line GBL, the reference gate line GRL, and the fifth conductive layer 1410 may be spaced apart from each other. The initialization gate line GBL, the reference gate line GRL, and the fifth conductive layer 1410 may include Al, Pt, Pd, Ag, Mg, Au, Ni, Nd, Ir, Cr, Li, Ca, Mo, Ti, W, and/or Cu, and may be formed of one or more layers including the materials described above.

Each of the initialization gate line GBL and the reference gate line GRL may extend in the first direction (e.g., the x direction) to pass through the first pixel circuit PC1 and the second pixel circuit PC2. Each of the initialization gate line GBL and the reference gate line GRL may pass through pixel circuits in the same row as the first pixel circuit PC1 and the second pixel circuit PC2.

The fifth conductive layer 1410 positioned in each of the first pixel circuit PC1 and the second pixel circuit PC2 may have an isolated shape. The fifth conductive layer 1410 located in the first pixel circuit PC1 and the fifth conductive layer 1410 located in the second pixel circuit PC2 may be spaced apart from each other, and may be substantially symmetrical to each other with respect to the imaginary line IML described above.

The fifth conductive layer 1410 may overlap the third conductive layer 1330 of the first pixel circuit PC1, the third conductive layer 1330 of the second pixel circuit PC2, and the second conductive layer 1320 passing through the first pixel circuit PC1 and the second pixel circuit PC2.

The fifth conductive layer 1410 may include the second hold electrode CEh2 of the hold capacitor Chd (see FIG. 10) and the second storage electrode CEs2 of the storage capacitor Cst (see FIG. 10). In other words, the second hold electrode CEh2 of the hold capacitor Chd and the second storage electrode CEs2 of the storage capacitor Cst may be integrally formed as a single body.

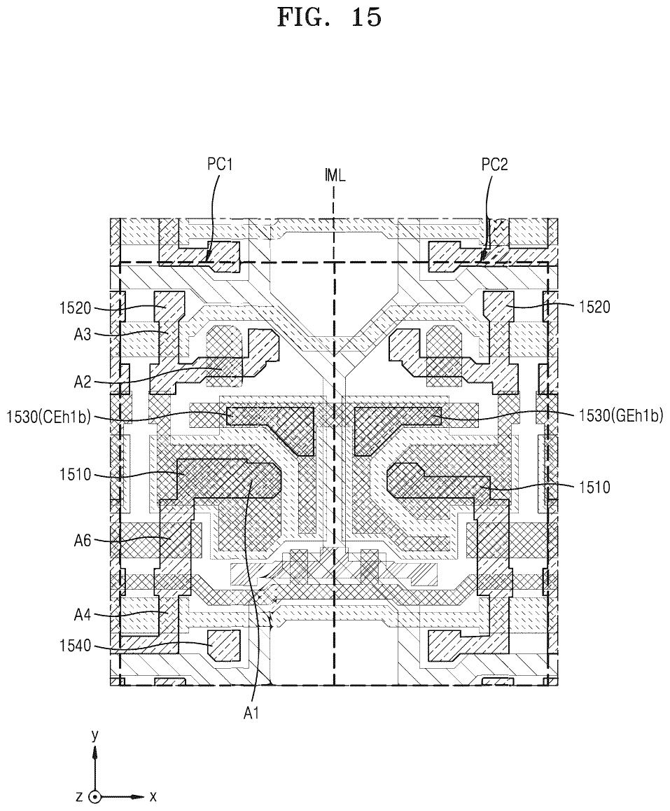

The first interlayer insulating layer 107 (see FIG. 10) may be formed on the structure described with reference to FIG. 14, and semiconductor patterns may be formed, as shown in FIG. 15. In FIG. 15, it is shown that a first oxide semiconductor pattern 1510, a second oxide semiconductor pattern 1520, a third oxide semiconductor pattern 1530, and a fourth oxide semiconductor pattern 1540 are formed on the first interlayer insulating layer 107 (see FIG. 10).

Referring to FIG. 15, the first oxide semiconductor pattern 1510, the second oxide semiconductor pattern 1520, the third oxide semiconductor pattern 1530, and the fourth oxide semiconductor pattern 1540 may be spaced apart from each other. Each of the first oxide semiconductor pattern 1510, the second oxide semiconductor pattern 1520, the third oxide semiconductor pattern 1530, and the fourth oxide semiconductor pattern 1540 may include ITZO, IGZO, or the like.

The first oxide semiconductor pattern 1510 located on each of the first pixel circuit PC1 and the second pixel circuit PC2 may have an isolated shape. The first oxide semiconductor pattern 1510 may include the first semiconductor layer A1, a fourth semiconductor layer A4, and a sixth semiconductor layer A6. In other words, the first semiconductor layer A1, the fourth semiconductor layer A4, and the sixth semiconductor layer A6 of the first pixel circuit PC1 may be integrally connected to each other, and the first semiconductor layer A1, the fourth semiconductor layer A4, and the sixth semiconductor layer A6 of the second pixel circuit PC2 may be integrally connected to each other. The first oxide semiconductor pattern 1510 may have a shape that is folded several times.

The first semiconductor layer A1, the fourth semiconductor layer A4, and the sixth semiconductor layer A6 may overlap the fifth conductive layer 1410 and the initialization gate line GBL described with reference to FIG. 14 and the fourth conductive layer 1340 described with reference to FIG. 13, respectively.

According to some embodiments, in a plan view, the first oxide semiconductor pattern 1510 of the first pixel circuit PC1 and the first oxide semiconductor pattern 1510 of the second pixel circuit PC2 may differ in shape. Part of the first oxide semiconductor pattern 1510 of the first pixel circuit PC1 may be located on the same row as the first pixel circuit PC, and may be located in a pixel circuit located on an adjacent column (e.g., an (i)^{th} row and (j−1)^{th} column).

The second oxide semiconductor pattern 1520 located in each of the first pixel circuit PC1 and the second pixel circuit PC2 may have an isolated shape. The second oxide semiconductor pattern 1520 may be bent to have an approximately “L” shape. The second oxide semiconductor pattern 1520 of the first pixel circuit PC1 and the second oxide semiconductor pattern 1520 of the second pixel circuit PC2 may be symmetrically arranged with respect to the imaginary line IML described above.

The second oxide semiconductor pattern 1520 may include a second semiconductor layer A2 of the second transistor T2 and a third semiconductor layer A3 of the third transistor T3. In other words, the second semiconductor layer A2 of the second transistor T2 and the third semiconductor layer A3 of the third transistor T3 may be integrally connected to each other.

The second semiconductor layer A2 and the third semiconductor layer A3 may overlap the first conductive layer 1310 described with reference to FIG. 13 and the reference gate line GRL described with reference to FIG. 14, respectively.

The third oxide semiconductor pattern 1530 located in each of the first pixel circuit PC1 and the second pixel circuit PC2 may have an isolated shape. The third oxide semiconductor pattern 1530 of the first pixel circuit PC1 and the third oxide semiconductor pattern 1530 of the second pixel circuit PC2 may be symmetrically arranged with respect to the imaginary line IML described above.

The third oxide semiconductor pattern 1530 may overlap the fifth conductive layer 1410 described with reference to FIG. 14 and the second conductive layer 1320 described with reference to FIG. 13. The third oxide semiconductor pattern 1530 may include the first upper hold electrode CEh1b, which is a sub-layer of the first hold electrode CEh1 of the hold capacitor Chd (see FIG. 10).

The fourth oxide semiconductor pattern 1540 may be located in the first pixel circuit PC1. The fourth oxide semiconductor pattern 1540 may be located at a position corresponding to one end of the first oxide semiconductor pattern 1510 of the first pixel circuit PC1 and may correspond to a kind of dummy electrode.

Each of the first oxide semiconductor pattern 1510, the second oxide semiconductor pattern 1520, the third oxide semiconductor pattern 1530, and the fourth oxide semiconductor pattern 1540 may include at least a partially conductive area. For example, a conductive process using plasma or the like may be performed on at least part of each of the first oxide semiconductor pattern 1510, the second oxide semiconductor pattern 1520, the third oxide semiconductor pattern 1530, and the fourth oxide semiconductor pattern 1540 may include at least a partially conductive area. According to some embodiments, an entire area of the third oxide semiconductor pattern 1530 including the first upper hold electrode CEh1b may be conductive to form the hold capacitor Chd (see FIG. 8).

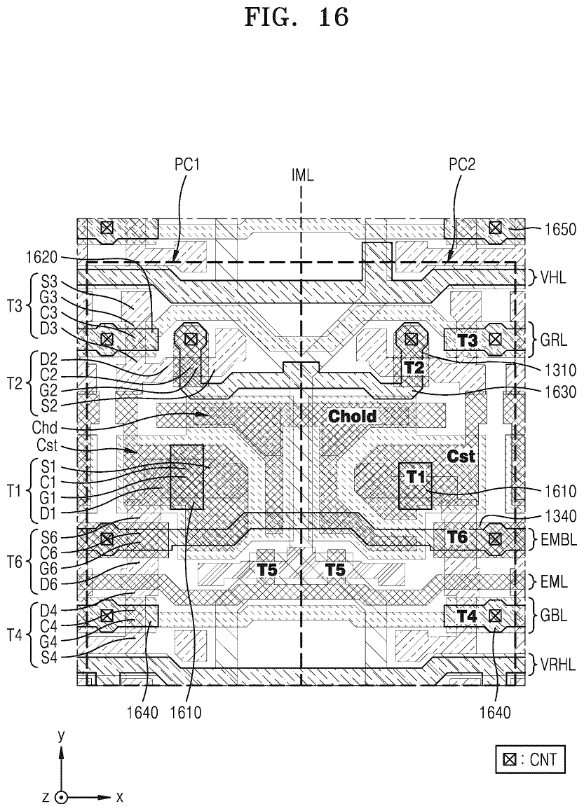

The third gate insulating layer 109 (see FIG. 10) may be formed on the structure shown in FIG. 15, and a gate line, a voltage line, and conductive layers (e.g., electrode layers) may be formed, as shown in FIG. 16.

Referring to FIG. 16, a horizontal initialization voltage line VHL, the second emission control line EMBL, a horizontal reference voltage line VRHL, and first to fourth electrode layers 1610, 1620, 1630, and 1640 may be formed on the third gate insulating layer 109 (see FIG. 10).

The horizontal initialization voltage line VHL, the second emission control line EMBL, the horizontal reference voltage line VRHL, and the first to fourth electrode layers 1610, 1620, 1630, and 1640 may include Al, Pt, Pd, Ag, Mg, Au, Ni, Nd, Ir, Cr, Li, Ca, Mo, Ti, W, and/or Cu, and may be formed of one or more layers including the materials described above.

The horizontal initialization voltage line VHL may extend in the first direction (e.g., the x direction) to pass through the first pixel circuit PC1 and the second pixel circuit PC2. The horizontal initialization voltage line VHL may be electrically connected to the initialization voltage line VL described below with reference to FIG. 18.

The second emission control line EMBL may extend in the first direction (e.g., the x direction) to pass through the first pixel circuit PC1 and the second pixel circuit PC2. The second emission control line EMBL may pass through pixel circuits arranged in the same row as the first pixel circuit PC1 and the second pixel circuit PC2.

The horizontal reference voltage line VRHL may extend in the first direction (e.g., the x direction) to pass through the first pixel circuit PC1 and the second pixel circuit PC2. The horizontal reference voltage line VRHL may be electrically connected to the reference voltage line VRL described below with reference to FIG. 18.

A first electrode layer 1610, a second electrode layer 1620, and a fourth electrode layer 1640 located in each of the first pixel circuit PC1 and the second pixel circuit PC2 may each have an isolated shape. The first, second, and fourth electrode layers 1610, 1620, and 1640 of the first pixel circuit PC1 and the first, second, and fourth electrode layers 1610, 1620, and 1640 of the second pixel circuit PC2 may be symmetrically arranged with respect to the imaginary line IML described above.

A third electrode layer 1630 may have an isolated shape and may extend in the first direction (e.g., the x direction). The third electrode layer 1630 may be arranged throughout the first pixel circuit PC1 and the second pixel circuit PC2. The third electrode layer 1630 may cross the imaginary line IML described above.

The first to fourth electrode layers 1610, 1620, 1630, and 1640 and the second emission control line EMBL may include a gate electrode of a transistor.

The first electrode layer 1610 of each of the first pixel circuit PC1 and the second pixel circuit PC2 may include the first gate electrode G1 of the first transistor T1. Referring to FIGS. 15 and 16, the first semiconductor layer A1 of the first transistor T1 may include the channel region C1 overlapping the first electrode layer 1610 and conductive regions S1 and D1 respectively arranged at opposite sides of the channel region C1. One of the conductive regions S1 and D1 may be a source region and the other one may be a drain region. The source region and the drain region may correspond to a source electrode and a drain electrode, respectively. Positions of the source region and the drain region may be interchanged depending on the properties of the transistor.

The second electrode layer 1620 of each of the first pixel circuit PC1 and the second pixel circuit PC2 may include a third gate electrode G3 of the third transistor T3. Referring to FIGS. 15 and 16, the third semiconductor layer A3 of the third transistor T3 may include a channel region C3 overlapping the second electrode layer 1620 and conductive regions S3 and D3 respectively arranged at opposite sides of the channel region C3. One of the conductive regions S3 and D3 may be a source region and the other one may be a drain region. The source region and the drain region may correspond to a source electrode and a drain electrode, respectively. Positions of the source region and the drain region may be interchanged depending on the properties of the transistor.

The second electrode layer 1620 may be electrically connected to the reference gate line GRL located below the third semiconductor layer A3 (see FIG. 15) through a contact hole CNT. Part of the second electrode layer 1620 and the reference gate line GRL may overlap each other with the channel region C3 of the third transistor T3 therebetween. Part of the reference gate line GRL overlapping the channel region C3 of the third transistor T3 may correspond to a lower gate electrode of the third transistor T3, and through this dual gate structure, the switching performance of the third transistor T3 may be relatively improved.

The third electrode layer 1630 may include a second gate electrode G2 of the second transistor T2. Referring to FIGS. 15 and 16, the second semiconductor layer A2 of the second transistor T2 may include a channel region C2 overlapping the third electrode layer 1630 and conductive regions S2 and D2 respectively located at opposite sides of the channel region C2. One of the conductive regions S2 and D2 may be a source region and the other one may be a drain region. The source region and the drain region may correspond to a source electrode and a drain electrode, respectively. Positions of the source region and the drain region may be interchanged depending on the properties of the transistor.

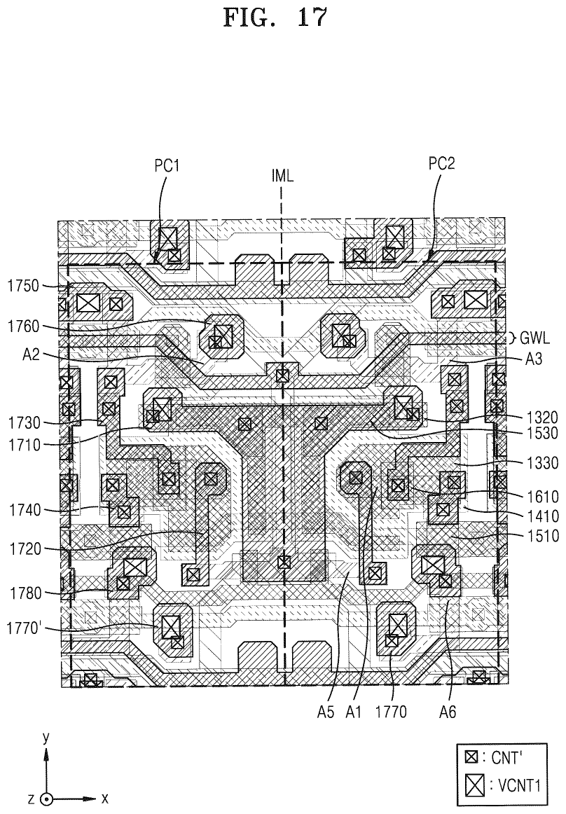

The third electrode layer 1630 may be electrically connected to the scan line GWL described below with reference to FIG. 17. The third electrode layer 1630 may be electrically connected to the first conductive layer 1310 located below the second semiconductor layer A2 (see FIG. 15) through the contact hole CNT. The third electrode layer 1630 and the first conductive layer 1310 may overlap each other with the channel region C2 of the second transistor T2 therebetween. The first conductive layer 1310 may correspond to a lower gate electrode of the second transistor T2, and through this dual gate structure, the switching performance of the second transistor T2 may be relatively improved.

The fourth electrode layer 1640 of each of the first pixel circuit PC1 and the second pixel circuit PC2 may include a fourth gate electrode G4 of the fourth transistor T4. Referring to FIGS. 15 and 16, the fourth semiconductor layer A4 of the fourth transistor T4 may include a channel region C4 overlapping the fourth electrode layer 1640 and conductive regions S4 and D4 respectively arranged at opposite sides of the channel region C4. One of the conductive regions S4 and D4 may be a source region and the other one may be a drain region. The source region and the drain region may correspond to a source electrode and a drain electrode, respectively. Positions of the source region and the drain region may be interchanged depending on the properties of the transistor.

The fourth electrode layer 1640 may be electrically connected to the initialization gate line GBL arranged below the fourth semiconductor layer A4 (see FIG. 15) through the contact hole CNT. Part of the fourth electrode layer 1640 and the initialization gate line GBL may overlap each other with the channel region C4 of the fourth transistor T4 therebetween. Part of the initialization gate line GBL overlapping the channel region C4 of the fourth transistor T4 may correspond to a lower gate electrode of the fourth transistor T4, and through this dual gate structure, the switching performance of the fourth transistor T4 may be relatively improved.

The second emission control line EMBL may include a sixth gate electrode G6 of the sixth transistor T6. Referring to FIGS. 15 and 16, the sixth semiconductor layer A6 of the sixth transistor T6 may include a channel region C6 overlapping the second emission control line EMBL and conductive regions S6 and D6 respectively arranged at opposite sides of the channel region C6. One of the conductive regions S6 and D6 may be a source region and the other one may be a drain region. The source region and the drain region may correspond to a source electrode and a drain electrode, respectively. Positions of the source region and the drain region may be interchanged depending on the properties of the transistor.

The second emission control line EMBL may be electrically connected to the fourth conductive layer 1340 arranged below the sixth semiconductor layer A6 (see FIG. 15) through the contact hole CNT. Part of the second emission control line EMBL and the fourth conductive layer 1340 may overlap each other with the channel region C6 of the sixth transistor T6 therebetween. The fourth conductive layer 1340 may correspond to a lower gate electrode of the sixth transistor T6, and through this dual gate structure, the switching performance of the fourth transistor T4 may be relatively improved.

The second interlayer insulating layer 111 (see FIG. 10) may be formed on the structure shown in FIG. 16, and a gate line and conductive layers (e.g., connection electrodes) may be formed, as shown in FIG. 17. FIG. 17 shows that the scan line GWL and first to eighth connection electrode 1710, 1720, 1730, 1740, 1750, 1760, 1770, and 1780 are formed on the second interlayer insulating layer 111 (see FIG. 10).

The scan line GWL and the first to eighth connection electrode 1710, 1720, 1730, 1740, 1750, 1760, 1770, and 1780 may include Al, Pt, Pd, Ag, Mg, Au, Ni, Nd, Ir, Cr, Li, Ca, Mo, Ti, W, and/or Cu, and may be formed of a layer or layers including the materials described above.

The scan line GWL may extend in the first direction (e.g., the x direction) to pass through the first pixel circuit PC1 and the second pixel circuit PC2. The scan line GWL may pass through pixel circuits arranged in the same row as the first pixel circuit PC1 and the second pixel circuit PC2.

The first connection electrode 1710 may have an isolated shape and may extend in the first direction (e.g., the x direction) to pass through the first pixel circuit PC1 and the second pixel circuit PC2. The first connection electrode 1710 may cross the imaginary line IML between the first pixel circuit PC1 and the second pixel circuit PC2.

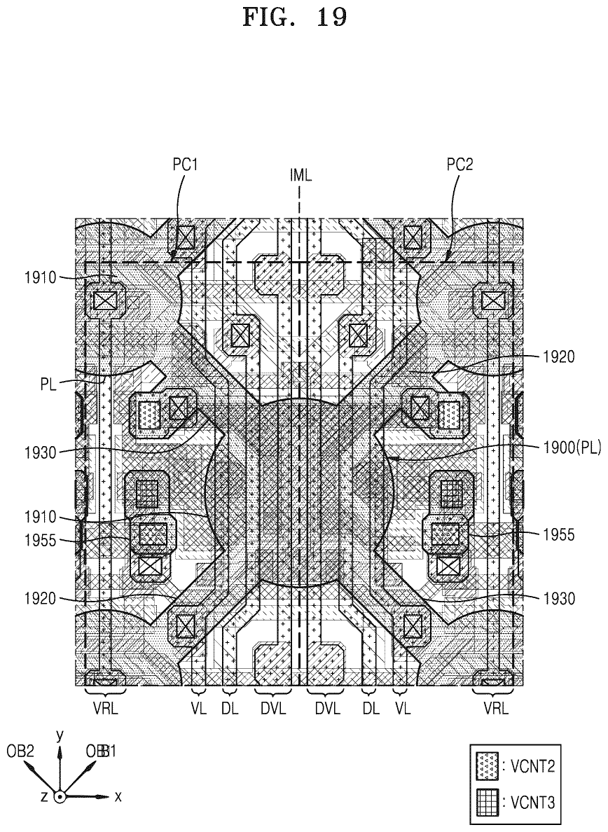

The first connection electrode 1710 may be electrically connected to the second conductive layer 1320 and the third oxide semiconductor pattern 1530 through contact holes CNT′. The first connection electrode 1710 may be electrically connected to the fifth semiconductor layer A5 of the fifth transistor T5 (see FIG. 16) through the contact hole CNT′. The first connection electrode 1710 may connect a voltage layer 1900 described below (see FIG. 19) and the fifth transistor T5 (see FIG. 16) to each other. The first connection electrode 1710 may be electrically connected to each of the voltage layer 1900 (see FIG. 19), the first lower hold electrode CEh1a, and the first upper hold electrode CEh1b.

The second connection electrode 1720 positioned in each of the first pixel circuit PC1 and the second pixel circuit PC2 may have an isolated shape. The second connection electrode 1720 may electrically connect the first transistor T1 (see FIG. 16) and the fifth transistor T5 (see FIG. 16) of each of the first pixel circuit PC1 and the second pixel circuit PC2. The second connection electrode 1720 may be electrically connected to the first semiconductor layer A1 of the first transistor T1 (see FIG. 16) through the contact hole CNT′, and may be electrically connected to the fifth semiconductor layer A5 of the fifth transistor T5 (see FIG. 16) through the contact hole CNT′. The second connection electrode 1720 may electrically connect the first transistor T1 (see FIG. 16) and the fifth transistor T5 (see FIG. 16) to each other. In each of the first pixel circuit PC1 and the second pixel circuit PC2, a contact hole CNT′ (see FIG. 17) corresponding to a connection point for electrical connection of the second connection electrode 1720 and the first semiconductor layer A1 may overlap the third conductive layer 1330 (see FIG. 14) and the fifth conductive layer 1410 (see FIG. 14). The third conductive layer 1330 (see FIG. 14) may be below the first semiconductor layer A1, and the fifth conductive layer 1410 (see FIG. 14) may be between the third conductive layer 1330 (see FIG. 14) and the first semiconductor layer A1. In a plan view, the entire of the contact hole CNT′ (see FIG. 17) corresponding to a connection point for electrical connection of the second connection electrode 1720 and the first semiconductor layer A1 may overlap the third conductive layer 1330 (see FIG. 14) and the fifth conductive layer 1410 (see FIG. 14). In a comparative example, in case that an edge of the third conductive layer 1330 (see FIG. 14) and/or an edge of the fifth conductive layer 1410 (see FIG. 14) is arranged below the contact hole CNT′ (see FIG. 17), a step structure due to the edge of the third conductive layer 1330 (see FIG. 14) and/or the edge of the fifth conductive layer 1410 (see FIG. 14) may be arranged below the contact hole CNT′. Because of the step structure, a problem such as an accidental or unintentional electrical connection between the fifth conductive layer 1410 (see FIG. 14) and the second connection electrode 1720 may occur. However, according to one or more embodiments, the entire of the contact hole CNT′ (see FIG. 17) corresponding to a connection point for electrical connection of the second connection electrode 1720 and the first semiconductor layer A1 may overlap the third conductive layer 1330 (see FIG. 14) and the fifth conductive layer 1410 (see FIG. 14). Accordingly, the accidental or unintentional electrical connection may be prevented.

The third connection electrode 1730 positioned in each of the first pixel circuit PC1 and the second pixel circuit PC2 may have an isolated shape. The third connection electrode 1730 may correspond to the first node described with reference to FIG. 8. The third connection electrode 1730 may electrically connect the first transistor T1 (see FIG. 16), the third transistor T3 (see FIG. 16), and the first storage electrode CEs1 of the storage capacitor Cst (see FIG. 16) of each of the first pixel circuit PC1 and the second pixel circuit PC2. The third connection electrode 1730 may be electrically connected to the first electrode layer 1610 corresponding to a first gate electrode of the first transistor T1 (see FIG. 16) through the contact hole CNT′, electrically connected to the third semiconductor layer A3 through the contact hole CNT′, and electrically connected to the third conductive layer 1330 through the contact hole CNT′.

The fourth connection electrode 1740 positioned in each of the first pixel circuit PC1 and the second pixel circuit PC2 may have an isolated shape. The fourth connection electrode 1740 may correspond to the second node described with reference to FIG. 8. The fourth connection electrode 1740 may electrically connect the second storage electrode CEs2 of the storage capacitor Cst (see FIG. 16), the second hold electrode CEh2, the first transistor T1 (see FIG. 16), and the sixth transistor T6 (see FIG. 16) to each other. The fourth connection electrode 1740 may be electrically connected to the fifth conductive layer 1410 including the second storage electrode CEs2 and the second hold electrode CEh2 through the contact hole CNT′, and may be electrically connected to the first oxide semiconductor pattern 1510 through the contact hole CNT′. A connection point of the fourth connection electrode 1740 and the first oxide semiconductor pattern 1510 may be positioned between an area corresponding to the first semiconductor layer A1 and an area corresponding to the sixth semiconductor layer A6 (see FIG. 15) within the first oxide semiconductor pattern 1510.

The fifth connection electrode 1750 positioned in each of the first pixel circuit PC1 and the second pixel circuit PC2 may have an isolated shape. The fifth connection electrode 1750 may be electrically connected to the third transistor T3 (see FIG. 16). The fifth connection electrode 1750 may be electrically connected to the third semiconductor layer A3 through the contact hole CNT′. The fifth connection electrode 1750 may be connected to the reference voltage line VRL (see FIG. 18) described below, and may transfer the reference voltage Vref (see FIG. 8) to the third transistor T3 (see FIG. 16).

The sixth connection electrode 1760 positioned in each of the first pixel circuit PC1 and the second pixel circuit PC2 may have an isolated shape. The sixth connection electrode 1760 may be electrically connected to the second transistor T2 (see FIG. 16). The sixth connection electrode 1760 may be electrically connected to the second transistor T2 (see FIG. 16) through the contact hole CNT′, and the sixth connection electrode 1760 may be connected to the data line DL (see FIG. 18) described below and may transfer the data signal DATA (see FIG. 8) to the second transistor T2 (see FIG. 16).

The seventh connection electrode 1770 positioned in the second pixel circuit PC2 may have an isolated shape. The seventh connection electrode 1770 may electrically connect the fourth transistor T4 (see FIG. 16) of the second pixel circuit PC2 to the initialization voltage line VL described below with reference to FIG. 18. The seventh connection electrode 1770 may be electrically connected to the fourth semiconductor layer A4 of the fourth transistor T4 (see FIG. 16) through the contact hole CNT′.

The fourth transistor T4 (see FIG. 16) positioned in the first pixel circuit PC1 may be electrically connected to an initialization voltage line passing through a pixel circuit adjacent to the first pixel circuit PC1. For example, part of the first oxide semiconductor pattern 1510 of the first pixel circuit PC1 may extend to an adjacent pixel circuit in the (i)^{th} row and a (j−1)^{th} column, and may be electrically connected to an initialization voltage line passing through the adjacent pixel circuit.

A dummy connection electrode 1770′ positioned in the first pixel circuit PC1 may have an isolated shape. The dummy connection electrode 1770′ may be electrically connected to the fourth oxide semiconductor pattern 1540 through the contact hole CNT′.

An eighth connection electrode 1780 positioned in each of the first pixel circuit PC1 and the second pixel circuit PC2 may have an isolated shape. The eighth connection electrode 1780 may be electrically connected to the sixth transistor T6 (see FIG. 16). The eighth connection electrode 1780 may be electrically connected to the sixth semiconductor layer A6 and the fourth semiconductor layer A4 through the contact hole CNT′. The eighth connection electrode 1780 may be electrically connected to the first oxide semiconductor pattern 1510 through the contact hole CNT′, and a connection point of the eighth connection electrode 1780 and the first oxide semiconductor pattern 1510 may be positioned between an area corresponding to the sixth semiconductor layer A6 and an area corresponding to the fourth semiconductor layer A4 within the first oxide semiconductor pattern 1510. The eighth connection electrode 1780 may electrically connect a pixel electrode of the light-emitting diode LED (see FIG. 8) to the fourth transistor T4 (see FIG. 16) and the sixth transistor T6 (see FIG. 16).

The first organic insulating layer 113 (see FIG. 10) may be formed on the structure described with reference to FIG. 17, and first via contact holes VCNT1 may be formed. Thereafter, as shown in FIG. 18, the data line DL, the data connection line DVL, the initialization voltage line VL, the reference voltage line VRL, a ninth connection electrode 1810, and a tenth connection electrode 1820 may be formed.

Referring to FIG. 18, each of the data line DL, the data connection line DVL, the initialization voltage line VL, and the reference voltage line VRL may extend in the second direction (e.g., the y direction). The data line DL, the data connection line DVL, the initialization voltage line VL, and the reference voltage line VRL passing through the first pixel circuit PC1 and the data line DL, the data connection line DVL, the initialization voltage line VL, and the reference voltage line VRL passing through the second pixel circuit PC2 may be substantially symmetrical to each other with respect to the imaginary line IML.

The data line DL passing through each of the first pixel circuit PC1 and the second pixel circuit PC2 may be electrically connected to the sixth connection electrode 1760 described with reference to FIG. 17 through the first via contact hole VCNT1, and may provide a data signal to the second transistor T2 (see FIG. 16).

The data connection line DVL passing through each of the first pixel circuit PC1 and the second pixel circuit PC2 may be electrically connected to pixel circuits in a column different from a column of the first pixel circuit PC1 and the second pixel circuit PC2.

The initialization voltage line VL passing through the second pixel circuit PC2 may be electrically connected to the seventh connection electrode 1770 (see FIG. 17) positioned in the second pixel circuit PC2 through the first via contact hole VCNT1 and may provide an initialization voltage to the fourth transistor T4 (see FIG. 16) of the second pixel circuit PC2.

The initialization voltage line VL passing through the first pixel circuit PC1 may be electrically connected to the dummy connection electrode 1770′ described with reference to FIG. 17 through the first via contact hole VCNT1. As described above with reference to FIG. 17, the fourth transistor T4 (see FIG. 16) positioned in the first pixel circuit PC1 may be electrically connected to an initialization voltage line passing through an adjacent pixel circuit adjacent to the first pixel circuit PC1.

The reference voltage line VRL passing through each of the first pixel circuit PC1 and the second pixel circuit PC2 may be electrically connected to the fifth connection electrode 1750 described with reference to FIG. 17 through the first via contact hole VCNT1, and may provide a reference voltage to the third transistor T3 (see FIG. 16).

The ninth connection electrode 1810 and the tenth connection electrode 1820 may each have an isolated shape. The ninth connection electrode 1810 positioned in each of the first pixel circuit PC1 and the second pixel circuit PC2 may be electrically connected to the first connection electrode 1710 described with reference to FIG. 17 through the first via contact hole VCNT1. The first connection electrode 1710 (see FIG. 17) and the ninth connection electrode 1810 may electrically connect a voltage layer 1900 described below and the hold capacitor Chd (see FIG. 8) to each other.

The tenth connection electrode 1820 positioned in each of the first pixel circuit PC1 and the second pixel circuit PC2 may be electrically connected to the eighth connection electrode 1780 described with reference to FIG. 17 through the first via contact hole VCNT1. The eighth connection electrode 1780 and the tenth connection electrode 1820 may electrically connect a pixel electrode of the light-emitting diode LED (see FIG. 8) to the fourth transistor T4 (see FIG. 16) and the sixth transistor T6 (see FIG. 16).

The second organic insulating layer 115 (see FIG. 10) may be formed on the structure described with reference to FIG. 18, and second via contact holes VCNT2 may be formed. FIG. 19 shows that the voltage layer 1900 described with reference to FIG. 8 and an eleventh connection electrode 1955 are formed on the second organic insulating layer 115 (see FIG. 10).

Referring to FIG. 19, the voltage layer 1900 may include main portions 1910 spaced apart from each other and bridge portions 1920 and 1930 connecting the main portions 1910 to each other. The main portions 1910 and the bridge portions 1920 and 1930 may be integrally connected to each other, and the self-resistance of the voltage layer 1900 may be relatively reduced through the structure described above. In a plan view, the connection structure of the main portions 1910 and the bridge portions 1920 and 1930 may have a mesh shape. According to some embodiments, the voltage layer 1900 may have the driving voltage line PL described with reference to FIG. 8. In other words, the voltage layer 1900 may have a function of the driving voltage line PL described with reference to FIG. 8.

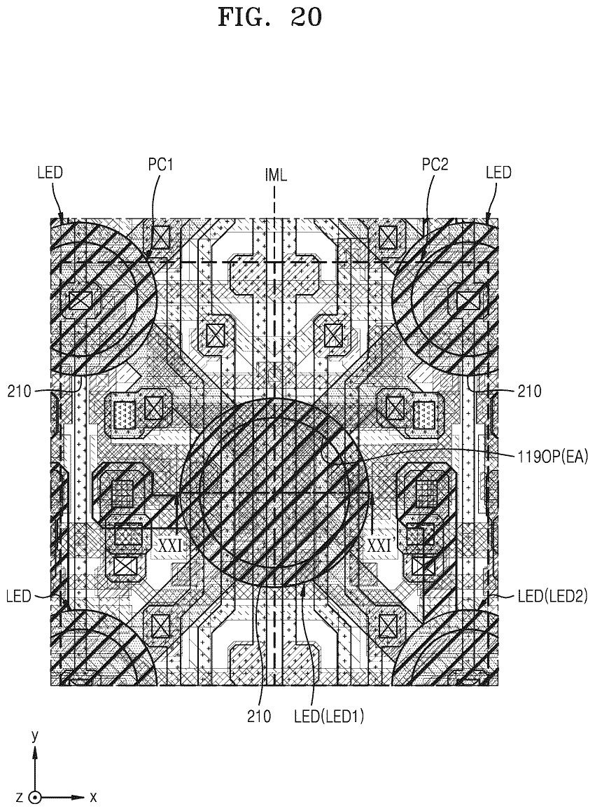

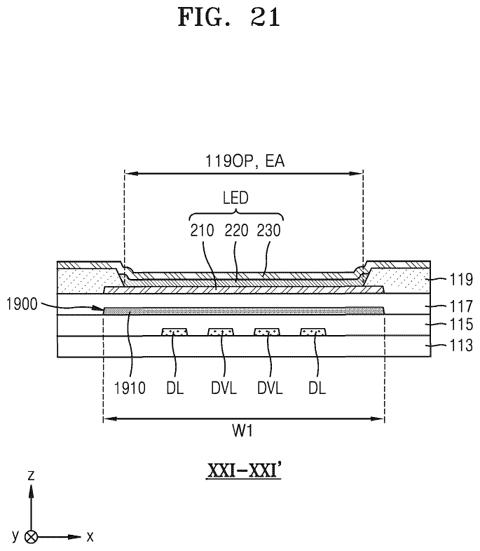

The main portion 1910 may overlap a voltage line or signal line thereunder. According to some embodiments, any of the main portions 1910 may be positioned on the imaginary line IML and may overlap the data line DL and the data connection line DVL passing through each of the first pixel circuit PC1 and the second pixel circuit PC2. Another one of the main portions 1910 may overlap the reference voltage line VRL passing through the first pixel circuit PC1. Another one of the main portions 1910 may overlap the reference voltage line VRL passing through the second pixel circuit PC2. The main portion 1910 may overlap an emission area EA (see FIG. 20) of the light-emitting diode LED (see FIG. 20) described below with reference to FIG. 20.

The bridge portions 1920 and 1930 may extend in a first diagonal direction OB1 and/or second diagonal direction OB2 crossing the first direction (e.g., the x direction) and the second direction (e.g., the y direction). Each of the bridge portions 1920 and 1930 may connect adjacent main portions 1910. According to some embodiments, a first bridge portion 1920 of the bridge portions 1920 and 1930 may extend in the first diagonal direction OB1 and integrally connect to two adjacent main portions 1910. A second bridge portion 1930 of the bridge portions 1920 and 1930 may extend in the second diagonal direction OB2 and integrally connect to two adjacent main portions 1910.

In some embodiments, the voltage layer 1900 may be electrically connected to a transistor or capacitor through the bridge portions 1920 and 1930.

A third bridge portion 1930 passing through the first pixel circuit PC1 may be electrically connected to the ninth connection electrode 1810 (see FIG. 18) positioned in the first pixel circuit PC1 through the second via contact hole VCNT2. The ninth connection electrode 1810 (see FIG. 18) may be electrically connected to the first connection electrode 1710 (see FIG. 17) positioned in the first pixel circuit PC1. The first connection electrode 1710 (see FIG. 17) may be electrically connected to the second conductive layer 1320 (see FIG. 13) including the first lower hold electrode CEh1a of the hold capacitor Chd, the third oxide semiconductor pattern 1530 (see FIG. 15) including the first upper hold electrode CEh1b of the hold capacitor Chd, and the fifth semiconductor layer A5 of the fifth transistor T5 (see FIG. 12). Accordingly, a driving voltage of the voltage layer 1900 may be transferred to the fifth transistor T5 of the first pixel circuit PC1 and the first hold electrode CEh1 of the hold capacitor Chd.

A second bridge portion 1920 passing through the second pixel circuit PC2 may be electrically connected to the ninth connection electrode 1810 (see FIG. 18) positioned in the second pixel circuit PC2 through the second via contact hole VCNT2. The ninth connection electrode 1810 may be electrically connected to the first connection electrode 1710 (see FIG. 17) positioned in the second pixel circuit PC2. The first connection electrode 1710 (see FIG. 17) may be electrically connected to the second conductive layer 1320 including the first lower hold electrode CEh1a of the hold capacitor Chd, the third oxide conductive pattern 1530 including the first upper hold electrode CEh1b of the hold capacitor Chd, and the fifth semiconductor layer A5 of the fifth transistor T5. Accordingly, the driving voltage of the voltage layer 1900 may be transferred to the fifth transistor T5 of the second pixel circuit PC2 and the first hold electrode CEh1 of the hold capacitor Chd.

The eleventh connection electrode 1955 positioned in each of the first pixel circuit PC1 and the second pixel circuit PC2 may have an isolated shape. Each eleventh connection electrode 1955 may be electrically connected to the tenth connection electrode 1820 (see FIG. 18) positioned in each of the first pixel circuit PC1 and the second pixel circuit PC2 through the second via contact hole VCNT2.

The third organic insulating layer 117 (see FIG. 10) may be formed on the structure described with reference to FIG. 19, and third via contact holes VCNT3 passing through the third organic insulating layer 117 (see FIG. 10) may be formed. The pixel electrodes 210 (see FIG. 20) of the light-emitting diode LED (see FIG. 20) described below with reference to FIG. 20 may be arranged on the third organic insulating layer 117. Each of the pixel electrodes 210 (see FIG. 20) may be electrically connected to the eleventh connection electrode 1955 of a corresponding pixel circuit through the third via contact hole VCNT3.

Although FIG. 19 shows the main portion 1910 having a circular shape, embodiments according to the present disclosure are not limited thereto. According to some embodiments, the main portion 1910 may have an elliptical or polygonal (rectangular, pentagonal, hexagonal, octagonal, etc.) shape.

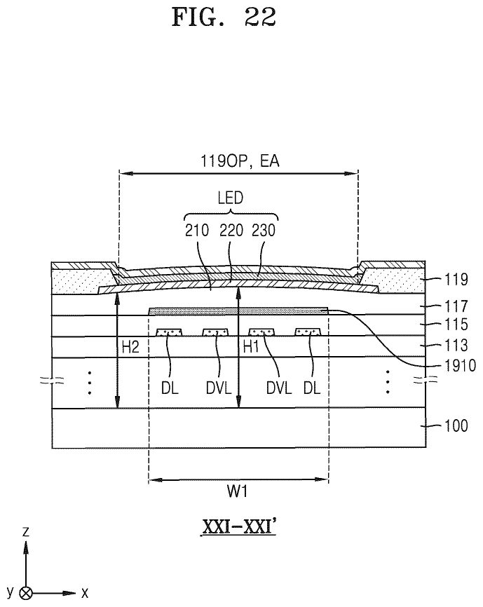

FIG. 20 is a plan view of light-emitting diodes located on pixel circuits according to some embodiments, FIG. 21 is a cross-sectional view taken along the line XXI-XXI′ in FIG. 20, According to some embodiments, and FIG. 22 is a cross-sectional view taken along the line XXI-XXI′ in FIG. 20, according to some embodiments. According to some embodiments, as shown in FIG. 20, the pixel electrode 210 may overlap the initialization voltage line VL (see FIG. 18). However, for convenience of description, the initialization voltage line VL (see FIG. 18) is omitted in each of FIGS. 21 and 22.

Referring to FIG. 20, the light-emitting diodes LED may be spaced apart from each other. FIG. 20 shows that four light-emitting diodes LED are arranged around any one light-emitting diode LED (hereinafter, referred to as “first light-emitting diode LED1”) electrically connected to the first pixel circuit PC1. The first light-emitting diode LED1 may overlap the first pixel circuit PC1 and the second pixel circuit PC2. For example, the first light-emitting diode LED1 may be positioned on the imaginary line IML between the first pixel circuit PC1 and the second pixel circuit PC2.

Any one light-emitting diode LED (hereinafter, referred to as “second light-emitting diode LED2”) of the four light-emitting diodes LED arranged around the first light-emitting diode LED1 may be electrically connected to the first pixel circuit PC1. The pixel electrode 210 of each of the first light-emitting diode LED1 and the second light-emitting diode LED2 may be electrically connected to a corresponding pixel circuit through the third via contact hole VCNT3 described with reference to FIG. 19.

Referring to FIGS. 20 and 21, the light-emitting diodes LED may each overlap the main portion 1910 of the corresponding voltage layer 1900. An emission area EA of each light-emitting diode LED may overlap the main portion 1910 of the voltage layer 1900.

As shown in FIG. 21, the main portion 1910 of the voltage layer 1900 may be located between lines located below the pixel electrode 210 and the main portion 1910 to provide signals, e.g., between the data lines DL and the data connection lines DVL. The main portion 1910 may prevent or reduce instances of parasitic capacitance occurring between each of the data lines DL and/or data connection lines DVL and the pixel electrode 210, thereby preventing or reducing degradation of display quality due to the parasitic capacitance.

In the embodiments described with reference to FIGS. 19 to 21, the voltage layer 1900, which corresponds to the driving voltage line PL described with reference to FIG. 8, has a voltage level (e.g., constant voltage) of the driving voltage ELVDD (see FIG. 8). However, embodiments according to the present disclosure are not limited thereto. According to some embodiments, the voltage layer 1900 between each of the data lines DL and/or data connection lines DVL and the pixel electrode 210 may have a voltage level (e.g., constant voltage) equal to the common voltage ELVSS (see FIG. 8), in which case a feature corresponding to the driving voltage line may be located on the same layer as the data line DL (see FIG. 18) or the like.

According to some embodiments, a width W1 of the main portion 1910 may be greater than a width of the emission area EA of each light-emitting diode LED, as shown in FIG. 21. The emission area EA of the light-emitting diode LED may be defined by the opening 119OP defined in the bank layer 119 overlapping the pixel electrode 210. The opening 119OP in the bank layer 119 may overlap the main portion 1910, and the data lines DL and the data connection lines DVL that are arranged below the main portion 1910. In one embodiment, the width W1 of the main portion 1910 may be greater than a width of the opening 119OP defined in the bank layer 119 overlapping the main portion 1910.

According to some embodiments, the width W1 of the main portion 1910 may be less than the width of the emission area EA of each light-emitting diode LED, as shown in FIG. 22. In other words, the width W1 of the main portion 1910 may be less than a width of the opening 119OP defined in the bank layer 119 overlapping the pixel electrode 210.

According to the embodiments described with reference to FIG. 21, the width W1 of the main portion 1910 is greater than the width of the emission area EA. Thus, a portion of the pixel electrode 210 corresponding to the emission area EA may be maintained in a relatively flat state. An upper surface of the portion of the pixel electrode 210 corresponding to the emission area EA may be substantially flat.

According to the embodiments described with reference to FIG. 22, the width W1 of the main portion 1910 is less than the width of the emission area EA. Thus, an upper surface of the third organic insulating layer 117 located below a portion of the pixel electrode 210 corresponding to the emission area EA may not be flat below the emission area EA. A first horizontal distance H1, from the substrate 100 to the pixel electrode 210 corresponding a central portion of the emission area EA, may be greater than a second horizontal distance H2, from the substrate 100 to the pixel electrode 210 corresponding an edge portion of the emission area EA. In the structure shown in FIG. 21, sufficient luminance in a front direction (e.g., the z direction) may be ensured. In the structure shown in FIG. 22, luminance in the front direction (e.g., z direction) and oblique directions may be increased.

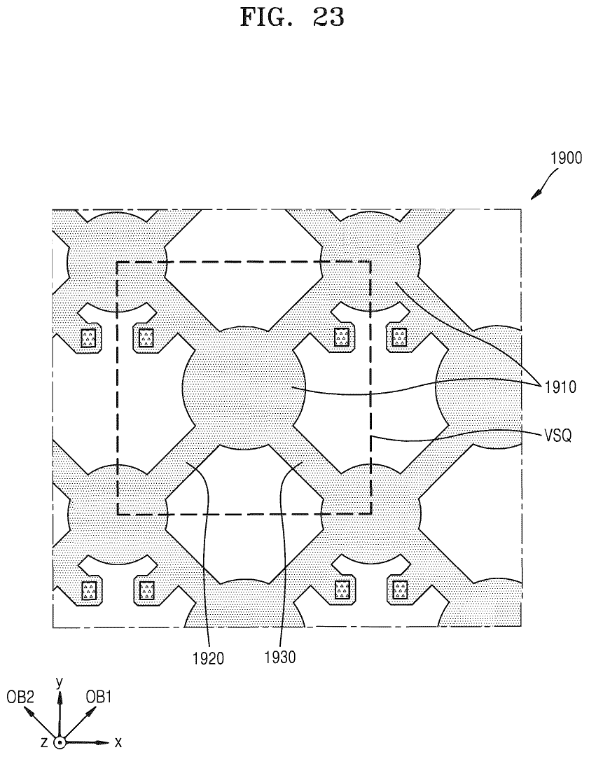

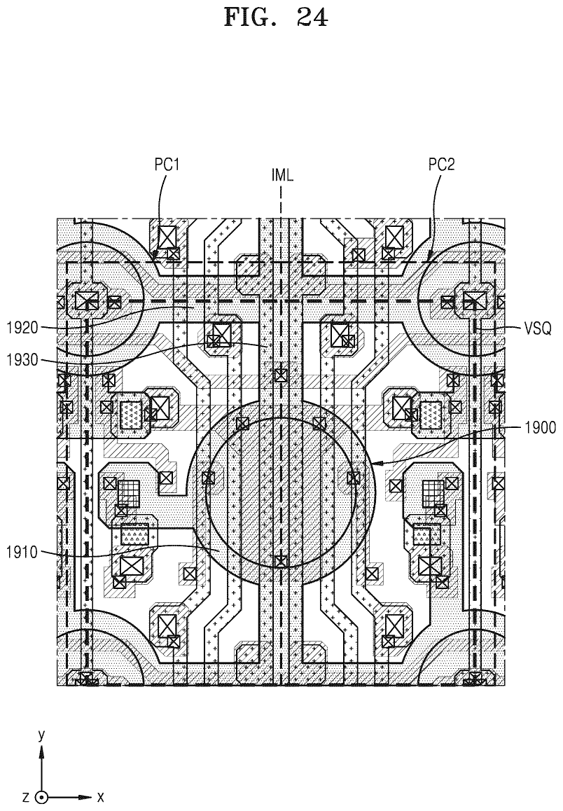

FIG. 23 is a plan view of a portion of the voltage layer 1900 of FIG. 19, and FIG. 24 is a plan view of the voltage layer 1900 on the first and second pixel circuits PC1 and PC2 according to some embodiments.

Referring to FIG. 23, the main portion 1910 may be spaced apart from each other. According to some embodiments, the main portions 1910 may be located at four corners of the imaginary rectangle VSQ centered on any one main portion 1910, respectively. The main portions 1910 may differ in size. In this regard, FIG. 23 shows that a size (or width) of the main portion 1910 positioned in the center of the imaginary rectangle VSQ is greater than a size (or width) of the main portion 1910 positioned in each of the corners. However, embodiments according to the present disclosure are not limited thereto. According to some embodiments, the size (or width) of the main portion 1910 positioned in the center of the imaginary rectangle VSQ may be less than the size (or width) of the main portion 1910 positioned in each of the corners.

In the embodiments described with reference to FIGS. 19 and 23, the first and second bridge portions 1920 and 1930 connecting the main portions 1910 of the voltage layer 1900 extend in the first diagonal direction OB1 and the second diagonal direction OB2. Accordingly, the main portion 1910 positioned in the center of the imaginary rectangle VSQ may be directly connected to the main portion 1910 positioned on the main portions positioned at the four corners of the imaginary rectangle VSQ.

According to some embodiments, as shown in FIG. 24, the first bridge portion 1920 and the second bridge portion 1930 may extend in the first direction (e.g., the x direction) and the second direction (e.g., the y direction), respectively. For example, two main portions 1910 adjacent to each other in the first direction (e.g., the x direction) from among the main portions 1910 positioned at the four corners of the imaginary rectangle VSQ may be connected to each other through the first bridge portion 1920 extending in the first direction (e.g., the x direction).

The main portion 1910 positioned in the center of the imaginary rectangle VSQ may be connected to the four main portions 1910 described with reference to FIG. 4, through the second bridge portion 1930 extending in the second direction (e.g., the y direction). For example, the second bridge portion 1930, which extends in the second direction (e.g., the +y direction) from the main portion 1910 positioned in the center of the imaginary rectangle VSQ, may be connected to the first bridge portion 1920 connecting two main portions 1910 respectively positioned at the corners of the imaginary rectangle VSQ. In addition, the second bridge portion 1930, which extends in the second direction (e.g., the −y direction) from the main portion 1910 positioned in the center of the imaginary rectangle VSQ, may be connected to the first bridge portion 1920 connecting two main portions 1910 respectively positioned at the corners of the imaginary rectangle VSQ. In other words, the main portion 1910 positioned in the center of the imaginary rectangle VSQ may be connected to the main portions 1910 positioned at the four corners of the imaginary rectangle VSQ through the second bridge portions 1930 connected to an upper portion and lower portion of the main portion 1910 and a connection structure of the second bridge portions 1930.

According to the one or more embodiments described above, through a shielding structure of a main portion of the voltage layer 1900, parasitic capacitance occurring between a signal providing data signals and a pixel electrode may be prevented or reduced. According to the one or more embodiments described above, a dual gate structure in which switching transistors are located below and over a semiconductor layer, thereby relatively improving switching performance. According to the one or more embodiments described above, oxide transistors may be included. Through the features described above, a display panel and electronic device having a high-speed driving or response speed and providing high-quality images may be provided.

According to some embodiments, a display panel and electronic device having a relatively high-speed response speed and providing relatively high-quality images may be provided. The characteristics described above are examples, and the characteristics of embodiments according to the present disclosure are not limited to those described above.

It should be understood that embodiments described herein should be considered in a descriptive sense only and not for purposes of limitation. Descriptions of features or aspects within each embodiment should typically be considered as available for other similar features or aspects in other embodiments. While aspects of one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a first pixel circuit and a second pixel circuit on a substrate and each comprising a driving transistor and a storage capacitor, the first pixel circuit and the second pixel circuit being adjacent to each other in a first direction;
data lines extending in a second direction crossing the first direction and electrically connected to the first pixel circuit and the second pixel circuit, respectively;
a first insulating layer on the data lines;
a voltage layer on the first insulating layer;
a second insulating layer on the voltage layer; and
a light-emitting diode comprising a pixel electrode on the second insulating layer, an opposite electrode on the pixel electrode, and an emission layer between the pixel electrode and the opposite electrode,
wherein the voltage layer comprises:
a plurality of main portions spaced apart from each other; and
bridge portions connecting the plurality of main portions, and
the main portions comprise a first main portion interposed between the data lines and the pixel electrode and overlapping the data lines and the pixel electrode.

2. The display panel of claim 1, wherein
a data line electrically connected to the first pixel circuit and a data line electrically connected to the second pixel circuit are arranged symmetrically with respect to an imaginary line between the first pixel circuit and the second pixel circuit.

3. The display panel of claim 2, further comprising
data connection lines configured to transmit data signals to pixel circuits other than the first pixel circuit and the second pixel circuit and passing through each of the first pixel circuit and the second pixel circuit, respectively,
wherein the first main portion overlaps the data connection lines.

4. The display panel of claim 3, wherein a data connection line passing through the first pixel circuit and a data connection line passing through the second pixel circuit are arranged symmetrically with respect to the imaginary line.

5. The display panel of claim 1, wherein
each of the first pixel circuit and the second pixel circuit further comprises a switching transistor electrically connected to the driving transistor and the voltage layer, and
a semiconductor layer of the driving transistor of each of the first pixel circuit and the second pixel circuit comprises a material different from a material of a semiconductor layer of the switching transistor,
wherein the semiconductor layer of the driving transistor comprises an oxide semiconductor material, and
the semiconductor layer of the switching transistor comprises polysilicon.

6. The display panel of claim 5, further comprising
a hold capacitor electrically connected to the driving transistor and the voltage layer;
a conductive layer below the semiconductor layer of the driving transistor; and
an insulating layer interposed between the conductive layer and the switching transistor,
wherein the hold capacitor comprises a first hold electrode electrically connected to the voltage layer and a second hold electrode overlapping the first hold electrode.

7. The display panel of claim 6, wherein
the storage capacitor comprises a first storage electrode and a second storage electrode that overlap each other, and
the conductive layer comprises the second storage electrode and the second hold electrode.

8. The display panel of claim 6, wherein
the first hold electrode comprises:
a first lower hold electrode below the conductive layer with the insulating layer therebetween; and
a first upper hold electrode positioned on an opposite side of the first lower hold electrode with the conductive layer therebetween,
wherein the first upper hold electrode comprises a material identical to that of the semiconductor layer of the driving transistor.

9. The display panel of claim 5, wherein
each of the first pixel circuit and the second pixel circuit further comprises:
a connection electrode electrically connecting the semiconductor layer of the driving transistor and the semiconductor layer of the switching transistor;
a first conductive layer below the semiconductor layer of the driving transistor; and
a second conductive layer between the first conductive layer and the semiconductor layer of the driving transistor,
wherein a connection point of the connection electrode and the semiconductor layer of the driving transistor overlaps the first conductive layer and the second conductive layer.

10. The display panel of claim 9, wherein
the storage capacitor of each of the first pixel circuit and the second pixel circuit comprises a first storage electrode and a second storage electrode overlapping each other, and
the first conductive layer includes the first storage electrode, and the second conductive layer includes the second storage electrode.

11. The display panel of claim 1, further comprising
a bank layer on the pixel electrode and comprising an opening that overlaps the pixel electrode,
wherein the opening defined in the bank layer overlaps the first main portion.

12. The display panel of claim 1, wherein
the main portions further comprise a second main portion, a third main portion, a fourth main portion, and a fifth main portion, the second to fifth main portions being arranged around the first main portion,
in a plan view, the second main portion, the third main portion, the fourth main portion, and the fifth main portion are at corners of an imaginary rectangle centered on the first main portion, respectively,
the second main portion and the third main portion are arranged in the first direction,
the fourth main portion is spaced apart from the second main portion in the second direction, and
the fifth main portion is spaced apart from the third main portion in the second direction.

13. The display panel of claim 1, wherein
the light-emitting diode is electrically connected to the first pixel circuit, and
the pixel electrode of the light-emitting diode overlaps an imaginary line between the first pixel circuit and the second pixel circuit.

14. The display panel of claim 1, wherein the voltage layer has a same voltage level as a voltage applied to the opposite electrode of the light-emitting diode.

15. An electronic device comprising:
a display panel; and
a lower cover forming an exterior of the electronic device and having an opening that exposes part of the display panel in a front surface thereof,
the display panel comprises:
a first pixel circuit and a second pixel circuit on a substrate and each comprising a driving transistor and a storage capacitor, the first pixel circuit and the second pixel circuit being adjacent to each other in a first direction;
data lines extending in a second direction crossing the first direction and electrically connected to the first pixel circuit and the second pixel circuit, respectively;
a first insulating layer on the data lines;
a voltage layer on the first insulating layer;
a second insulating layer on the voltage layer; and
a light-emitting diode comprising a pixel electrode on the second insulating layer, an opposite electrode on the pixel electrode, and an emission layer between the pixel electrode and the opposite electrode,
wherein the voltage layer comprises:
a plurality of main portions spaced apart from each other; and
bridge portions connecting the plurality of main portions, and
the main portions comprise a first main portion interposed between the data lines and the pixel electrode and overlapping the data lines and the pixel electrode.

16. The electronic device of claim 15, wherein
a data line electrically connected to the first pixel circuit and a data line electrically connected to the second pixel circuit are arranged symmetrically with respect to an imaginary line between the first pixel circuit and the second pixel circuit.

17. The electronic device of claim 16, wherein the display panel further comprises:
data connection lines configured to transmit data signals to pixel circuits other than the first pixel circuit and the second pixel circuit and passing through each of the first pixel circuit and the second pixel circuit, respectively; and
a data connection line passing through the first pixel circuit and a data connection line passing through the second pixel circuit are arranged symmetrically with respect to the imaginary line,
wherein the first main portion overlaps the data connection lines.

18. The electronic device of claim 17, wherein
the display panel further comprises a bank layer on the pixel electrode and comprising an opening that overlaps the pixel electrode, and
the opening defined in the bank layer overlaps the first main portion.

19. The electronic device of claim 15, wherein
each of the first pixel circuit and the second pixel circuit further comprises:
a switching transistor electrically connected to the driving transistor and the voltage layer;
a connection electrode electrically connecting a semiconductor layer of the driving transistor and a semiconductor layer of the switching transistor;
a first conductive layer below the semiconductor layer of the driving transistor; and
a second conductive layer between the first conductive layer and the semiconductor layer of the driving transistor,
wherein a semiconductor layer of the driving transistor of each of the first pixel circuit and the second pixel circuit comprises a material different from a material of a semiconductor layer of the switching transistor, and
a connection point of the connection electrode and the semiconductor layer of the driving transistor overlaps the first conductive layer and the second conductive layer.

20. The display panel of claim 19, wherein
the storage capacitor of each of the first pixel circuit and the second pixel circuit comprises a first storage electrode and a second storage electrode overlapping each other, and
the first conductive layer includes the first storage electrode, and the second conductive layer includes the second storage electrode.
